(19) United States
(12) Patent Application Publication
(10) Pub. No.: US 2025/0323817 A1
(43) Pub. Date: Oct. 16, 2025

(54) TECHNIQUES FOR PROBABILISTIC CONSTELLATION SHAPING IN WI-FI SYSTEMS

(71) Applicant: QUALCOMM Incorporated, San Diego, CA (US)

(72) Inventors: Eugene BAIK, Sunnyvale, CA (US); Bin TIAN, San Diego, CA (US); Jialing Li CHEN, San Diego, CA (US)

(21) Appl. No.: 18/889,678

(22) Filed: Sep. 19, 2024

Related U.S. Application Data
(60) Provisional application No. 63/634,203, filed on Apr. 15, 2024.

(51) Int. Cl. H04L 27/34; H03M 13/11; H04L 1/00

(52) U.S. Cl. CPC H04L 27/3483; H03M 13/11; H04L 1/0003

(57) ABSTRACT

This disclosure provides methods, components, devices and systems for techniques for probabilistic constellation shaping in Wi-Fi systems. Some aspects more specifically relate to a transmitter (e.g., transmitting wireless device) that supports constellation shaping. For example, the transmitter that supports constellation shaping may include a modulator capable of receiving separate streams of parity bits and constellation shaped systematic bits and modulating the separate streams of parity bits and constellation shaped systematic bits, such that a structure of the stream of constellation shaped systematic bits may be maintained during modulation to exploit the constellation shaping. Other aspects more specifically relate to parsing modulated symbols over multiple spatial streams (e.g., after constellation shaping).

### CROSS REFERENCE

The present application for patent claims the benefit of U.S. Provisional Patent Application No. 63/634,203 by BAIK et al., entitled “TECHNIQUES FOR PROBABILISTIC CONSTELLATION SHAPING IN WI-FI SYSTEMS,” filed Apr. 15, 2024, assigned to the assignee hereof, and expressly incorporated by reference herein.

### TECHNICAL FIELD

This disclosure relates generally to wireless communication and, more specifically, to techniques for probabilistic constellation shaping in Wi-Fi systems.

### DESCRIPTION OF THE RELATED TECHNOLOGY

Wireless communication networks are widely deployed to provide various types of communication content such as voice, video, packet data, messaging, broadcast, and so on. Some wireless communication networks may be capable of supporting communication with multiple users by sharing the available system resources (such as time, frequency, or power). Further, a wireless communication network may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM), among other examples. Wireless communication devices may communicate in accordance with any one or more of such wireless communication technologies, and may include wireless stations (STAs), wireless access points (APs), user equipment (UEs), network entities, or other wireless nodes.

In some wireless local-area networks (WLANs) (e.g., Wi-Fi systems), transmitting and receiving devices, such as APs and STAs, may support the use of various modulation and coding schemes (MCSs) to transmit and receive data so as to take advantage of wireless channel conditions, for example, to increase throughput, reduce latency, or enforce various quality of service (QoS) parameters. For example, existing technology (such as IEEE 802.11ax standard amendment protocols) supports the use of quadrature amplitude modulation (QAM) in which a bitstream may be input into a QAM modulator to form QAM symbols, which may be mapped to subcarriers of one or more orthogonal frequency-division multiplexing (OFDM) symbol for transmission.

### SUMMARY

The systems, methods, and devices of this disclosure each have several innovative aspects, no single one of which is solely responsible for the desirable attributes disclosed herein.

One innovative aspect of the subject matter described in this disclosure can be implemented in a method for wireless communications by a first wireless device is described. The method may include receiving a set of multiple (e.g., a plurality of) information bits for transmission, applying constellation shaping to the set of multiple information bits to generate a set of multiple shaped information bits, encoding the set of multiple shaped information bits to generate a stream of parity bits based on an encoding rate and a modulation order associated with generation of a set of multiple modulation symbols, where a stream of systematic bits corresponds to the set of multiple shaped information bits, and transmitting the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on a modulation and coding scheme (MCS), and where all systematic bits of the stream of systematic bits and all parity bits of the stream of parity bits are used to generate the set of multiple modulation symbols based on a relationship between the encoding rate and the modulation order.

Another innovative aspect of the subject matter described in this disclosure can be implemented in a first wireless device for wireless communications is described. The first wireless device may include a processing system that includes processor circuitry and memory circuitry that stores code. The processing system may be configured to cause the first wireless device to receive a set of multiple information bits for transmission, apply constellation shaping to the set of multiple information bits to generate a set of multiple shaped information bits, encode the set of multiple shaped information bits to generate a stream of parity bits based on an encoding rate and a modulation order associated with generation of a set of multiple modulation symbols, where a stream of systematic bits corresponds to the set of multiple shaped information bits, and transmit the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

Another innovative aspect of the subject matter described in this disclosure can be implemented in a first wireless device for wireless communications is described. The first wireless device may include means for receiving a set of multiple information bits for transmission, means for applying constellation shaping to the set of multiple information bits to generate a set of multiple shaped information bits, means for encoding the set of multiple shaped information bits to generate a stream of parity bits based on an encoding rate and a modulation order associated with generation of a set of multiple modulation symbols, where a stream of systematic bits corresponds to the set of multiple shaped information bits, and means for transmitting the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

Another innovative aspect of the subject matter described in this disclosure can be implemented in a non-transitory computer-readable medium storing code for wireless communications is described. The code may include instructions executable by one or more processors to receive a set of multiple information bits for transmission, apply constellation shaping to the set of multiple information bits to generate a set of multiple shaped information bits, encode the set of multiple shaped information bits to generate a stream of parity bits based on an encoding rate and a modulation order associated with generation of a set of multiple modulation symbols, where a stream of systematic bits corresponds to the set of multiple shaped information bits, and transmit the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

In some examples of the method, first wireless devices, and non-transitory computer-readable medium described herein, the encoding rate may be based on an encoding composition, and the encoding composition may be based on a first quantity of parity bits from the stream of parity bits per codeword generated based on the encoding and based at least in part on a second quantity of systematic bits from the stream of systematic bits per codeword generated based on the encoding.

Some examples of the method, first wireless devices, and non-transitory computer-readable medium described herein may further include operations, features, means, or instructions for communicating a control message indicating the modulation order, the encoding composition, or both, wherein the set of multiple modulation symbols is based on the modulation order, the encoding composition, or both.

In some examples of the method, first wireless devices, and non-transitory computer-readable medium described herein, the modulation order, the encoding composition, or both, may be pre-configured at the first wireless device, and the modulation order, the encoding composition, or both, may be based on the MCS.

In some examples of the method, first wireless devices, and non-transitory computer-readable medium described herein, the stream of parity bits may include a set of multiple parity bit segments, and the stream of systematic bits may include a set of multiple systematic bit segments, and each codeword may include a parity bit segment of the set of multiple parity bit segments and a systematic bit segment of the set of multiple systematic bit segments. In such cases, the method, first wireless devices, and non-transitory computer-readable medium described herein may further include operations, features, means, or instructions for adjusting the first quantity of parity bits in each codeword and the second quantity of systematic bits in each codeword on adjusting the encoding composition, where a ratio between the adjusted first quantity of parity bits and the adjusted second quantity of systematic bits matches a ratio between a third quantity of bits used to generate the sign of each component and a fourth quantity of bits used to generate the amplitude of each component.

In some examples of the method, first wireless devices, and non-transitory computer-readable medium described herein, a first sign of the first component may be based on a first group of parity bits of the stream of parity bits, a first amplitude of the first component may be based on a first group of systematic bits of the stream of systematic bits, a second sign of the second component may be based on a second group of parity bits of the stream of parity bit, and a second amplitude of the second component may be based on a second group of systematic bits of the stream of systematic bits.

In some examples of the method, first wireless devices, and non-transitory computer-readable medium described herein, a first sign of the first component may be based on a first group of parity bits of the stream of parity bits, a first amplitude of the first component may be based on a first group of systematic bits of the stream of systematic bits and a third group of parity bits from the stream of parity bits, a second sign of the second component may be based on a second group of parity bits of the stream of parity bit, and a second amplitude of the second component may be based on a second group of systematic bits of the stream of systematic bits and a fourth group of parity bits from the stream of parity bits.

Some examples of the method, first wireless devices, and non-transitory computer-readable medium described herein may further include operations, features, means, or instructions for generating a second modulation symbol of the set of multiple modulation symbols that includes a third component and a fourth component, where a sign of each component in the second modulation symbol may be based on a respective second group of parity bits from the stream of parity bits, and where an amplitude of each component in the second modulation symbol may be based on a respective second group of systematic bits from the stream of systematic bits.

Some examples of the method, first wireless devices, and non-transitory computer-readable medium described herein may further include operations, features, means, or instructions for generating a second modulation symbol of the set of multiple modulation symbols that includes a third component and a fourth component, where a sign of each component in the second modulation symbol may be based on a respective second group of parity bits from the stream of parity bits, and where an amplitude of each component in the second modulation symbol may be based on a respective second group of systematic bits from the stream of systematic bits and a respective third group of parity bits from the stream of parity bits.

In some examples of the method, first wireless devices, and non-transitory computer-readable medium described herein, the stream of parity bits includes a set of multiple parity bit segments and the method, apparatuses, and non-transitory computer-readable medium may include further operations, features, means, or instructions for generating a first set of modulation symbols of the set of multiple modulation symbols based on a first codeword including a first parity bit segment of the set of multiple parity bit segments and a first systematic bit segment of the set of multiple systematic bit segments and generating a second set of modulation symbols of the set of multiple modulation symbols based on a second codeword including a second parity bit segment of the set of multiple parity bit segments and a second systematic bit segment of the set of multiple systematic bit segments.

Some examples of the method, first wireless devices, and non-transitory computer-readable medium described herein may further include operations, features, means, or instructions for parsing the set of multiple modulation symbols into a set of multiple streams of modulation symbols.

Some examples of the method, first wireless devices, and non-transitory computer-readable medium described herein may further include operations, features, means, or instructions for parsing the stream of parity bits into a set of multiple streams of parity bits, parsing the stream of systematic bits into a set of multiple streams of systematic bits, and generating, via a respective modulator, a respective subset of the set of multiple modulation symbols based on a respective stream of parity bits and a respective stream of systematic bits.

Some examples of the method, first wireless devices, and non-transitory computer-readable medium described herein may further include operations, features, means, or instructions for parsing the set of multiple information bits between a set of multiple shapers, where each shaper of the set of multiple shapers may be associated with a different modulation order, and where applying the constellation shaping to the set of multiple information bits may include operations, features, means, or instructions for applying, via each shaper of the set of multiple shapers, the constellation shaping to a respective set of information bits from the set of multiple information bits to generate a respective stream of shaped information bits and interleaving the respective streams of information bits to generate a set of multiple interleaved, shaped information bits, wherein encoding the set of multiple shaped information bits includes encoding the set of multiple interleaved, shaped information bits.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows a pictorial diagram of an example wireless communication network.

FIG. 2 shows an example of a transmitter that supports techniques for probabilistic constellation shaping in Wi-Fi systems.

FIGS. 3A and 3B show examples of transmitters that supports techniques for probabilistic constellation shaping in Wi-Fi systems.

FIGS. 4A and 4B show examples of bitstream parsing schemes that supports techniques for probabilistic constellation shaping in Wi-Fi systems.

FIG. 5 shows an example of a modulation scheme that supports techniques for probabilistic constellation shaping in Wi-Fi systems.

FIG. 6 shows an example of a modulation scheme that supports techniques for probabilistic constellation shaping in Wi-Fi systems.

FIGS. 7 and 8 show block diagrams of devices that support techniques for probabilistic constellation shaping in Wi-Fi systems in accordance with one or more aspects of the present disclosure.

FIG. 9 shows a block diagram of an example wireless communication device that supports techniques for probabilistic constellation shaping in Wi-Fi systems.

FIG. 10 shows a flowchart illustrating an example process performable by or at a first wireless device that supports techniques for probabilistic constellation shaping in Wi-Fi systems.

Like reference numbers and designations in the various drawings indicate like elements.

### DETAILED DESCRIPTION

The following description is directed to some particular examples for the purposes of describing innovative aspects of this disclosure. However, a person having ordinary skill in the art will readily recognize that the teachings herein can be applied in a multitude of different ways. Some or all of the described examples may be implemented in any device, system or network that is capable of transmitting and receiving radio frequency (RF) signals according to one or more of the Institute of Electrical and Electronics Engineers (IEEE) 802.11 standards, the IEEE 802.15 standards, the Bluetooth® standards as defined by the Bluetooth Special Interest Group (SIG), or the Long Term Evolution (LTE), 3G, 4G, 5G (New Radio (NR)) or 6G standards promulgated by the 3rd Generation Partnership Project (3GPP), among others. The described examples can be implemented in any suitable device, component, system or network that is capable of transmitting and receiving RF signals according to one or more of the following technologies or techniques: code division multiple access (CDMA), time division multiple access (TDMA), orthogonal frequency division multiplexing (OFDM), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple-input multiple-output (MIMO) and multi-user (MU)-MIMO (MU-MIMO). The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), a non-terrestrial network (NTN), or an internet of things (IOT) network.

Various aspects relate generally to the implementation of constellation shaping (e.g., probabilistic constellation shaping) in Wi-Fi systems. Some aspects more specifically relate to a transmitter (e.g., transmitting wireless device) that supports constellation shaping. For example, the transmitter that supports constellation shaping may include a modulator capable of receiving separate streams of parity bits and constellation shaped systematic bits, such that a structure of the stream of constellation shaped systematic bits may be maintained during modulation to exploit the constellation shaping. Other aspects more specifically relate to modulation of the separate streams of parity bits and constellation shaped systematic bits. For example, the modulator (e.g., of the transmitter that supports constellation shaping) may generate modulation symbols each including a first component (e.g., first signal component) and a second component (e.g., second signal component), where a sign of each component is based on respective groups of parity bits from the stream of parity bits and an amplitude of each component is based on respective groups of constellation shaped systematic bits from the stream of constellation shaped systematic bits.

Particular aspects of the subject matter described in this disclosure can be implemented to realize one or more of the following potential advantages. In some examples, by feeding separate streams of parity bits and constellation shaped systematic bits to the modulator and separately mapping each stream to components of a modulation symbol, the described techniques can be used to maintain the structure of the stream of constellation shaped systematic bits during modulation, which may further enable a signal used to transmit modulation symbols to attain a Gaussian distribution of signal energy (e.g., enable the signal to attain a threshold entropy while remaining within a threshold power consumption). Attaining a Gaussian distribution of signal energy may further result in increased signal capacity and increased received symbol energy relative to noise.

Other aspects more specifically relate to parsing modulated symbols over multiple spatial streams (e.g., after constellation shaping). For example, in some cases, the transmitter that supports constellation shaping may include a stream parser after the modulator to distribute modulation symbols (e.g., generated by the modulator) across multiple spatial streams. In some other examples, the transmitter that supports constellation shaping may include a pair of stream parser (e.g., prior to modulation), where a first stream parser distributes the stream of parity bits across multiple modulators and a second stream parser distributes the stream of constellation shaped systematic bits across the multiple modulators, where each of the multiple modulators generates modulation symbols (e.g., based on respective parity bits and constellation shaped systematic bits) for a spatial stream of the multiple spatial streams. Other aspects more specifically relate to matching a modulation and coding scheme (MCS) of the modulator with a combination of an encoding rate of an encoder (e.g., of the transmitting wireless device) and a modulation order of the modulator to enable the modulator to map all parity bits of the stream of parity bits and all constellation shaped systematic bits of the stream of constellation shaped systematic bits to modulation symbols.

Particular aspects of the subject matter described in this disclosure can be implemented to realize one or more of the following potential advantages. By parsing the modulation symbols to multiple spatial streams, the described techniques can further be used to increase radio link capacity. Additionally, or alternatively, by matching the MCS of the modulator with the combination of the encoding rate of the encoder and the modulation order of the modulator, the described techniques can further be used to avoid a second phase of modulation, resulting in decreased complexity and increased performance (e.g., as compared to when the second phase of modulation is performed).

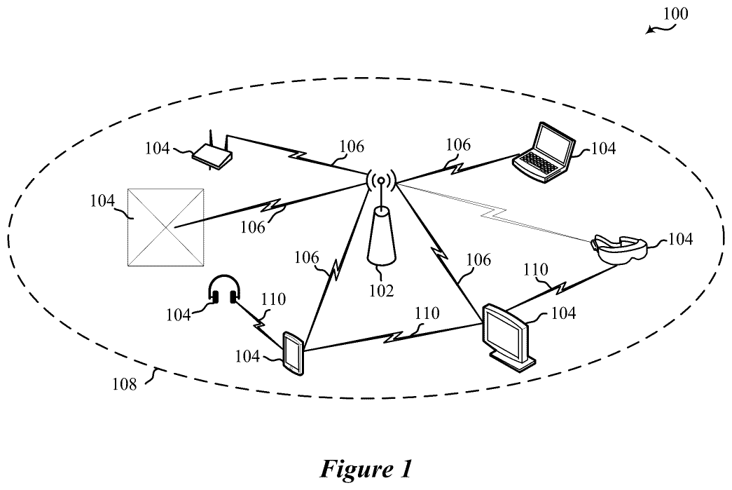

FIG. 1 shows a pictorial diagram of an example wireless communication network 100. According to some aspects, the wireless communication network 100 can be an example of a wireless local area network (WLAN) such as a Wi-Fi network. For example, the wireless communication network 100 can be a network implementing at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11be, 802.11bf, and 802.11bn). In some other examples, the wireless communication network 100 can be an example of a cellular radio access network (RAN), such as a 5G or 6G RAN that implements one or more cellular protocols such as those specified in one or more 3GPP standards. In some other examples, the wireless communication network 100 can include a WLAN that functions in an interoperable or converged manner with one or more cellular RANs to provide greater or enhanced network coverage to wireless communication devices within the wireless communication network 100 or to enable such devices to connect to a cellular network's core, such as to access the network management capabilities and functionality offered by the cellular network core. In some other examples, the wireless communication network 100 can include a WLAN that functions in an interoperable or converged manner with one or more personal area networks, such as a network implementing Bluetooth or other wireless technologies, to provide greater or enhanced network coverage or to provide or enable other capabilities, functionality, applications or services.

The wireless communication network 100 may include numerous wireless communication devices including at least one wireless access point (AP) 102 and any number of wireless stations (STAs) 104. While only one AP 102 is shown in FIG. 1, the wireless communication network 100 can include multiple APs 102. The AP 102 can be or represent various different types of network entities including, but not limited to, a home networking AP, an enterprise-level AP, a single-frequency AP, a dual-band simultaneous (DBS) AP, a tri-band simultaneous (TBS) AP, a standalone AP, a non-standalone AP, a software-enabled AP (soft AP), and a multi-link AP (also referred to as an AP multi-link device (MLD)), as well as cellular (such as 3GPP, 4G LTE, 5G or 6G) base stations or other cellular network nodes such as a Node B, an evolved Node B (cNB), a gNB, a transmission reception point (TRP) or another type of device or equipment included in a radio access network (RAN), including Open-RAN (O-RAN) network entities, such as a central unit (CU), a distributed unit (DU) or a radio unit (RU).

Each of the STAs 104 also may be referred to as a mobile station (MS), a mobile device, a mobile handset, a wireless handset, an access terminal (AT), a user equipment (UE), a subscriber station (SS), or a subscriber unit, among other examples. The STAs 104 may represent various devices such as mobile phones, other handheld or wearable communication devices, netbooks, notebook computers, tablet computers, laptops, Chromebooks, augmented reality (AR), virtual reality (VR), mixed reality (MR) or extended reality (XR) wireless headsets or other peripheral devices, wireless earbuds, other wearable devices, display devices (for example, TVs, computer monitors or video gaming consoles), video game controllers, navigation systems, music or other audio or stereo devices, remote control devices, printers, kitchen appliances (including smart refrigerators) or other household appliances, key fobs (for example, for passive keyless entry and start (PKES) systems), Internet of Things (IoT) devices, and vehicles, among other examples.

A single AP 102 and an associated set of STAs 104 may be referred to as a basic service set (BSS), which is managed by the respective AP 102. FIG. 1 additionally shows an example coverage area 108 of the AP 102, which may represent a basic service area (BSA) of the wireless communication network 100. The BSS may be identified by STAs 104 and other devices by a service set identifier (SSID), as well as a basic service set identifier (BSSID), which may be a medium access control (MAC) address of the AP 102. The AP 102 may periodically broadcast beacon frames (“beacons”) including the BSSID to enable any STAs 104 within wireless range of the AP 102 to “associate” or re-associate with the AP 102 to establish a respective communication link 106 (hereinafter also referred to as a “Wi-Fi link”), or to maintain a communication link 106, with the AP 102. For example, the beacons can include an identification or indication of a primary channel used by the respective AP 102 as well as a timing synchronization function (TSF) for establishing or maintaining timing synchronization with the AP 102. The AP 102 may provide access to external networks to various STAs 104 in the wireless communication network 100 via respective communication links 106.

To establish a communication link 106 with an AP 102, each of the STAs 104 is configured to perform passive or active scanning operations (“scans”) on frequency channels in one or more frequency bands (for example, the 2.4 GHZ, 5 GHZ, 6 GHz, 45 GHz, or 60 GHz bands). To perform passive scanning, a STA 104 listens for beacons, which are transmitted by respective APs 102 at periodic time intervals referred to as target beacon transmission times (TBTTs). To perform active scanning, a STA 104 generates and sequentially transmits probe requests on each channel to be scanned and listens for probe responses from APs 102. Each STA 104 may identify, determine, ascertain, or select an AP 102 with which to associate in accordance with the scanning information obtained through the passive or active scans, and to perform authentication and association operations to establish a communication link 106 with the selected AP 102. The selected AP 102 assigns an association identifier (AID) to the STA 104 at the culmination of the association operations, which the AP 102 uses to track the STA 104.

As a result of the increasing ubiquity of wireless networks, a STA 104 may have the opportunity to select one of many BSSs within range of the STA 104 or to select among multiple APs 102 that together form an extended service set (ESS) including multiple connected BSSs. For example, the wireless communication network 100 may be connected to a wired or wireless distribution system that may enable multiple APs 102 to be connected in such an ESS. As such, a STA 104 can be covered by more than one AP 102 and can associate with different APs 102 at different times for different transmissions. Additionally, after association with an AP 102, a STA 104 also may periodically scan its surroundings to find a more suitable AP 102 with which to associate. For example, a STA 104 that is moving relative to its associated AP 102 may perform a “roaming” scan to find another AP 102 having more desirable network characteristics such as a greater received signal strength indicator (RSSI) or a reduced traffic load.

In some examples, STAs 104 may form networks without APs 102 or other equipment other than the STAs 104 themselves. One example of such a network is an ad hoc network (or wireless ad hoc network). Ad hoc networks may alternatively be referred to as mesh networks or peer-to-peer (P2P) networks. In some examples, ad hoc networks may be implemented within a larger network such as the wireless communication network 100. In such examples, while the STAs 104 may be capable of communicating with each other through the AP 102 using communication links 106, STAs 104 also can communicate directly with each other via direct wireless communication links 110. Additionally, two STAs 104 may communicate via a direct wireless communication link 110 regardless of whether both STAs 104 are associated with and served by the same AP 102. In such an ad hoc system, one or more of the STAs 104 may assume the role filled by the AP 102 in a BSS. Such a STA 104 may be referred to as a group owner (GO) and may coordinate transmissions within the ad hoc network. Examples of direct wireless communication links 110 include Wi-Fi Direct connections, connections established by using a Wi-Fi Tunneled Direct Link Setup (TDLS) link, and other P2P group connections.

In some networks, the AP 102 or the STAs 104, or both, may support applications associated with high throughput or low-latency requirements, or may provide lossless audio to one or more other devices. For example, the AP 102 or the STAs 104 may support applications and use cases associated with ultra-low-latency (ULL), such as ULL gaming, or streaming lossless audio and video to one or more personal audio devices (such as peripheral devices) or AR/VR/MR/XR headset devices. In scenarios in which a user uses two or more peripheral devices, the AP 102 or the STAs 104 may support an extended personal audio network enabling communication with the two or more peripheral devices. Additionally, the AP 102 and STAs 104 may support additional ULL applications such as cloud-based applications (such as VR cloud gaming) that have ULL and high throughput requirements.

As indicated above, in some implementations, the AP 102 and the STAs 104 may function and communicate (via the respective communication links 106) according to one or more of the IEEE 802.11 family of wireless communication protocol standards. These standards define the WLAN radio and baseband protocols for the physical (PHY) and MAC layers. The AP 102 and STAs 104 transmit and receive wireless communications (hereinafter also referred to as “Wi-Fi communications” or “wireless packets”) to and from one another in the form of PHY protocol data units (PPDUs).

Each PPDU is a composite structure that includes a PHY preamble and a payload that is in the form of a PHY service data unit (PSDU). The information provided in the preamble may be used by a receiving device to decode the subsequent data in the PSDU. In instances in which a PPDU is transmitted over a bonded or wideband channel, the preamble fields may be duplicated and transmitted in each of multiple component channels. The PHY preamble may include both a legacy portion (or “legacy preamble”) and a non-legacy portion (or “non-legacy preamble”). The legacy preamble may be used for packet detection, automatic gain control and channel estimation, among other uses. The legacy preamble also may generally be used to maintain compatibility with legacy devices. The format of, coding of, and information provided in the non-legacy portion of the preamble is associated with the particular IEEE 802.11 wireless communication protocol to be used to transmit the payload.

The APs 102 and STAs 104 in the wireless communication network 100 may transmit PPDUs over an unlicensed spectrum, which may be a portion of spectrum that includes frequency bands traditionally used by Wi-Fi technology, such as the 2.4 GHZ, 5 GHz, 6 GHZ, 45 GHZ, and 60 GHz bands. Some examples of the APs 102 and STAs 104 described herein also may communicate in other frequency bands that may support licensed or unlicensed communications. For example, the APs 102 or STAs 104, or both, also may be capable of communicating over licensed operating bands, where multiple operators may have respective licenses to operate in the same or overlapping frequency ranges. Such licensed operating bands may map to or be associated with frequency range designations of FR1 (410 MHZ-7.125 GHZ), FR2 (24.25 GHz-52.6 GHz), FR3 (7.125 GHz-24.25 GHZ), FR4a or FR4-1 (52.6 GHz-71 GHZ), FR4 (52.6 GHz-114.25 GHZ), and FR5 (114.25 GHZ-300 GHz).

Each of the frequency bands may include multiple sub-bands and frequency channels (also referred to as subchannels). The terms “channel” and “subchannel” may be used interchangeably herein, as each may refer to a portion of frequency spectrum within a frequency band (for example, a 20 MHz, 40 MHZ, 80 MHZ, or 160 MHZ portion of frequency spectrum) via which communication between two or more wireless communication devices can occur. For example, PPDUs conforming to the IEEE 802.11n, 802.11ac, 802.11ax, 802.11be and 802.11bn standard amendments may be transmitted over one or more of the 2.4 GHZ, 5 GHZ, or 6 GHz bands, each of which is divided into multiple 20 MHz channels. As such, these PPDUs are transmitted over a physical channel having a minimum bandwidth of 20 MHz, but larger channels can be formed through channel bonding. For example, PPDUs may be transmitted over physical channels having bandwidths of 40 MHz, 80 MHZ, 160 MHz, 240 MHZ, 320 MHz, 480 MHz, or 640 MHz by bonding together multiple 20 MHz channels.

An AP 102 may determine or select an operating or operational bandwidth for the STAs 104 in its BSS and select a range of channels within a band to provide that operating bandwidth. For example, the AP 102 may select sixteen 20 MHz channels that collectively span an operating bandwidth of 320 MHz. Within the operating bandwidth, the AP 102 may typically select a single primary 20 MHz channel on which the AP 102 and the STAs 104 in its BSS monitor for contention-based access schemes. In some examples, the AP 102 or the STAs 104 may be capable of monitoring only a single primary 20 MHz channel for packet detection (for example, for detecting preambles of PPDUs). Conventionally, any transmission by an AP 102 or a STA 104 within a BSS must involve transmission on the primary 20 MHz channel. As such, in conventional systems, the transmitting device must contend on and win a TXOP on the primary channel to transmit anything at all. However, some APs 102 and STAs 104 supporting ultra-high reliability (UHR) communications or communication according to the IEEE 802.11bn standard amendment can be configured to operate, monitor, contend and communicate using multiple primary 20 MHz channels. Such monitoring of multiple primary 20 MHz channels may be sequential such that responsive to determining, ascertaining or detecting that a first primary 20 MHz channel is not available, a wireless communication device may switch to monitoring and contending using a second primary 20 MHz channel. Additionally, or alternatively, a wireless communication device may be configured to monitor multiple primary 20 MHZ channels in parallel. In some examples, a first primary 20 MHz channel may be referred to as a main primary (M-Primary) channel and one or more additional, second primary channels may each be referred to as an opportunistic primary (O-Primary) channel. For example, if a wireless communication device measures, identifies, ascertains, detects, or otherwise determines that the M-Primary channel is busy or occupied (such as due to an overlapping BSS (OBSS) transmission), the wireless communication device may switch to monitoring and contending on an O-Primary channel. In some examples, the M-Primary channel may be used for beaconing and serving legacy client devices and an O-Primary channel may be specifically used by non-legacy (for example, UHR- or IEEE 802.11bn-compatible) devices for opportunistic access to spectrum that may be otherwise under-utilized.

Puncturing is a wireless communication technique that enables a wireless communication device (such as either an AP 102 or a STA 104) to transmit and receive wireless communications over a portion of a wireless channel exclusive of one or more particular subchannels (hereinafter also referred to as “punctured subchannels”). Puncturing specifically may be used to exclude one or more subchannels from the transmission of a PPDU, including the signaling of the preamble, to avoid interference from a static source, such as an incumbent system, or to avoid interference of a more dynamic nature such as that associated with transmissions by other wireless communication devices in overlapping BSSs (OBSSs). The transmitting device (such as an AP 102 or a STA 104) may puncture the subchannels on which there is interference and in essence spread the data of the PPDU to cover the remaining portion of the bandwidth of the channel. For example, if a transmitting device determines (for example, detects, identifies, ascertains, or calculates), in association with a contention operation, that one or more 20 MHz subchannels of a wider bandwidth wireless channel are busy or otherwise not available, the transmitting device implement puncturing to avoid communicating over the unavailable subchannels while still utilizing the remaining portions of the bandwidth. Accordingly, puncturing enables a transmitting device to improve or maximize throughput, and in some instances reduce latency, by utilizing as much of the available spectrum as possible. Static puncturing in particular makes it possible to consistently use wideband channels in environments or deployments where there may be insufficient contiguous spectrum available, such as in the 5 GHz and 6 GHz bands.

Transmitting and receiving devices AP 102 and STA 104 may support the use of various modulation and coding schemes (MCSs) to transmit and receive data in the wireless communication network 100 so as to optimally take advantage of wireless channel conditions, for example, to increase throughput, reduce latency, or enforce various quality of service (QoS) parameters. For example, existing technology (such as IEEE 802.11ax standard amendment protocols) supports the use of up to 1024-QAM, where a modulated symbol carries 10 bits. To further improve peak data rate, each of the AP 102 or the STA 104 may employ use of 4096-QAM (also referred to as “4k QAM”), which enables a modulated symbol to carry 12 bits. 4k QAM may enable massive peak throughput with a maximum theoretical PHY rate of 10 bps/Hz/subcarrier/spatial stream, which translates to 23 Gbps with 5/6 LDPC code (10 bps/Hz/subcarrier/spatial stream*996*4 subcarriers*8 spatial streams/13.6 μs per OFDM symbol). The AP 102 or the STA 104 using 4096-QAM may enable a 20% increase in data rate compared to 1024-QAM given the same coding rate, thereby allowing users to obtain higher transmission efficiency.

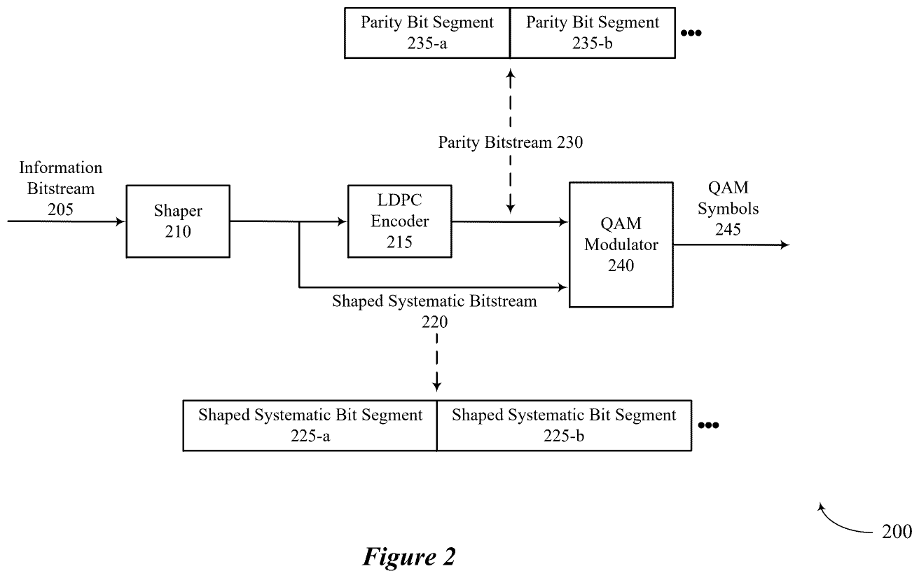

FIG. 2 shows an example of a transmitter 200 that supports techniques for probabilistic constellation shaping in Wi-Fi systems. According to some aspects, the transmitter 200 may be part of a WLAN such as a Wi-Fi network (e.g., system). For example, the transmitter 200 may support at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11be, 802.11bf, and 802.11bn).

In some wireless communications systems, such as the Wi-Fi network, wireless devices (e.g., transmitters 200 and receivers), such as APs 102 and STAs 104, may support the use of various MCSs to transmit and receive data so as to optimally take advantage of wireless channel conditions, for example, to increase throughput, reduce latency, or enforce various QoS parameters. For example, existing technology (such as IEEE 802.11ax standard amendment protocols) supports the use of QAM in which a bitstream may be input into a QAM modulator 240 to form QAM symbols 245, which may be mapped to subcarriers of one or more orthogonal frequency-division OFDM symbol for transmission (e.g., using a single spatial stream, Nₛₛ=1).

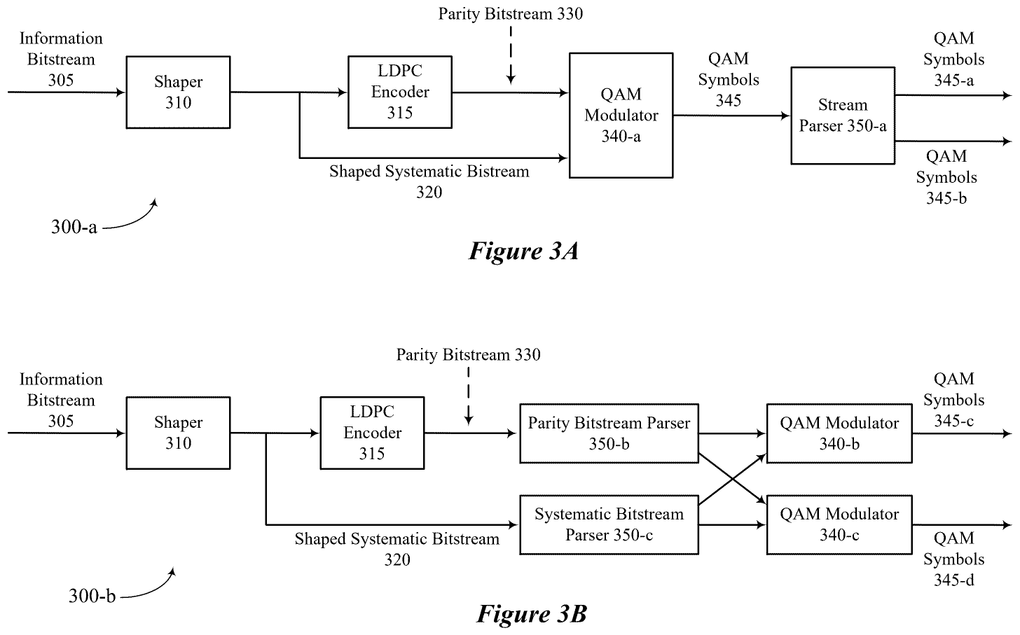

In such cases (e.g., Nₛₛ=1), an encoder, such as an LDPC encoder 215, of a transmitting wireless device may receive an information bitstream 205, may generate a systematic bitstream correspond to the information bitstream 205, and may encode (e.g., and rate match) the information bitstream 205 to generate a parity bitstream 230 (e.g., and repetition bits), where the parity bitstream 230 is based on the information bitstream 205. A serializer (e.g., of the transmitting wireless device) at an output of the LDPC encoder 215 may receive the systematic bitstream and the parity bitstream 230 and may construct one or more LDPC codewords (e.g., codeword grouping), where each LDPC codeword includes a group of systematic bits (e.g., from the systematic bitstream), which may be referred to as a systematic bit segment, appended with a group of parity bits (e.g., from the parity bitstream 230), which may be referred to as a parity bit segment 235. In such cases, the one or more LDPC codewords may form a single, serialized bitstream to be fed to a single QAM modulator 240. Thus, for a single spatial stream (e.g., Nₛₛ=1), the single QAM modulator 240 (e.g., of the transmitting wireless device) may receive the serialized bitstream and may generate one or more QAM symbols 245 based on the received serialized bitstream. Transmitting wireless devices supporting multiple spatial streams (e.g., Nₛₛ≥2) may be described further with reference to FIGS. 3A and 3B.

To generate one or more QAM symbols 245, the QAM modulator 240 may map incremental groups of bits (e.g., systematic bits, parity bits, or both) from the serialized bitstream to constellation points (e.g., symbols) of a constellation associated with the QAM modulator 240, where each constellation point represents a QAM symbol 245. That is, the QAM modulator 240 may use a specific MCS for generation of the one or more QAM symbols 245, where the MCS defines at least one of the constellation, the modulation order of the one or more QAM symbols, and a size of the group of bits (e.g., group sizing). In such cases, the constellation may be associated with a uniform distribution. In other words, values (e.g., 0 or 1) of each bit of the serialized bitstream may be equally likely, such that each constellation point of the constellation may be associated with an equal (e.g., same) usage frequency (e.g., probability or likelihood of use). However, different constellation points may be associated with different energy and average power (e.g., for transmission). That is, the constellation points may be arranged on a grid defined by a horizontal axis (e.g., I component) and a vertical axis (e.g., Q component), where constellation points located further from an origin (e.g., intersection of the horizontal axis and vertical axis) are associated with a higher energy than constellation points located closer to the origin. Thus, some signals may be generated based on a set of constellation points that are located further from the origin, resulting in high average power.

Accordingly, in some cases, the transmitting wireless device may perform constellation shaping on the information bitstream 205, such that the constellation (e.g., associated with the QAM modulator 240) may be associated with a non-uniform distribution in which constellation points of the constellation are associated with variable usage frequencies. In such cases, the variable usage frequencies may result in constellation points closer to the origin being associated with a higher usage frequency than those located further from the origin. Such as non-uniform distribution may result in a Gaussian distribution of energy associated with a signal (e.g., generated based on QAM symbols 245 output from the QAM modulator 240), which may enable the signal to attain a threshold (e.g., maximum entropy, or ability to carry information, while remaining within a threshold (e.g., maximum) average power consumption associated with the transmitting wireless device.

To support constellation shaping, the transmitting wireless device may include a shaper 210 prior to the LDPC encoder 215 to shape the information bitstream 205 into a shaped systematic bitstream 220 (e.g., corresponding to the information bitstream 205), such that values (e.g., 0 or 1) of each bit of the shaped systematic bitstream 220 may not be equally likely (e.g., may be associated with a non-uniform distribution) which may result in a non-uniform distribution of a constellation associated with the QAM modulator 240. In such cases, the non-uniform distribution may be based on a structure of the shaped systematic bitstream 220 (e.g., the structure of the shaped systematic bits in the shaped systematic bitstream 220 may be based on the shaping). According to existing transmitting wireless devices, as described previously, the transmitting wireless device may encode the shaped systematic bitstream 220 to generate a parity bitstream 230, where the parity bitstream 230 is based on the shaped systematic bitstream 220. The serializer at the output of the LDPC encoder 215 may receive the shaped systematic bitstream 220 and the parity bitstream 230 and may construct a serialized bitstream of one or more LDPC codewords, where each LDPC codeword includes a shaped systematic bit segment 225 appended with a parity bit segment 235. Thus, the QAM modulator 240 may receive the serialized bitstream output by the serializer and may generate one or more QAM symbols 245 based on the serialized bitstream. However, generating one or more QAM symbols 245 based on the single serialized bitstream may negate the shaping performed by the shaper 210. That is, the QAM modulator 240 receiving shaped systematic bits as part of the single serialized bitstream may result in the QAM modulator 240 not accounting for the structure of shaped systematic bits. The structure of the shaped systematic bits may be what enables the non-uniform distribution of the constellation associated with the QAM modulator 240, such that not accounting for the structure may result in the non-uniform distribution not occurring. In other words, mapping of the bits of the single serialized bitstream to constellation points may result in an unintended non-uniform distribution that may not result in a Gaussian distribution of energy.

Accordingly, techniques described herein may enable a transmitting wireless device, such as the transmitter 200, to support constellation shaping. In particular, the transmitter 200 may support constellation shaping for a single spatial stream (e.g., Nₛₛ=1). For example, a shaper 210 may receive an information bitstream 205 (e.g., set of information bits) and may shape (e.g., alter) bits of the information bitstream 205 such that, by the end of a QAM modulation process (e.g., at a QAM modulator 240), a frequency usage of constellation points (e.g., of a given QAM modulation order associated with the QAM modulator 240) may be probabilistically shaped to be non-uniform (e.g., be associated with a non-uniform distribution). Thus, the shaper 210 may output a shaped systematic bitstream 220 (e.g., including a set of shaped systematic bits) associated with a given structure (e.g., based on the shaping), where the shaped systematic bitstream 220 corresponds to the information bitstream 205. In such cases, the structure may be generated such that shaped systematic bits of the shaped systematic bitstream 220 may not be altered and the shaped systematic bitstream 220 may not be segmented or broken up.

An LDPC encoder 215 (e.g., and rate matcher) may receive the shaped systematic bitstream 220 from the shaper 210 and may generate a parity bitstream 230 (e.g., and repetition bits) based on the shaped systematic bitstream 220. In some cases, the parity bitstream 230 may include one or more parity bit segments 235 and the shaped systematic bitstream 220 may include one or more shaped systematic bit segments 225, where a combination of a parity bit segment 235 and a shaped systematic bit segment 225 forms an LDPC codeword (e.g., according to an LDPC codeword composition, an encoding composition). For example, a first LDCP codeword may include a parity bit segment 235-a and a shaped systematic bit segment 225-a and a second LDPC codeword may include a parity bit segment 235-b and a shaped systematic bit segment 225-b. Thus, the one or more parity bit segments 235 and the one or more shaped systematic bit segments 225 may form up to N (e.g., one or more) LDPC codewords. In such cases, a quantity of shaped systematic bits (e.g., of the shaped systematic bitstream 220) and a quantity of parity bits (e.g., of the parity bitstream 230) delivered by the LDPC encoder 215 per LDPC codeword may be defined by an encoding composition, where the encoding composition defines (e.g., is associated with) an effective coding rate of the LDPC encoder 215. That is, an effective coding rate of the LDPC encoder 215 may differ from a baseline encoding rate (e.g., specified by an MCS value) based on the encoding composition.

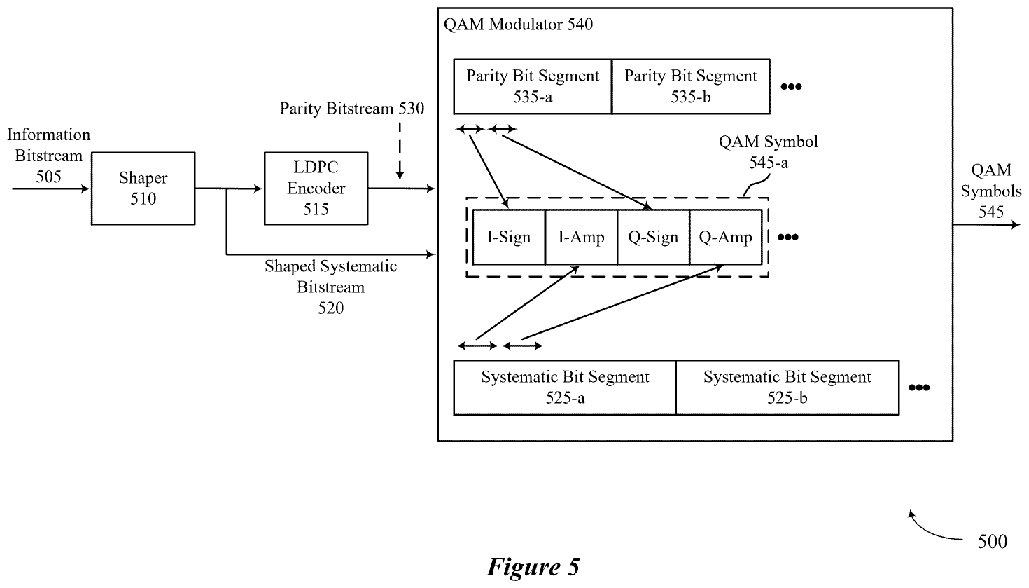

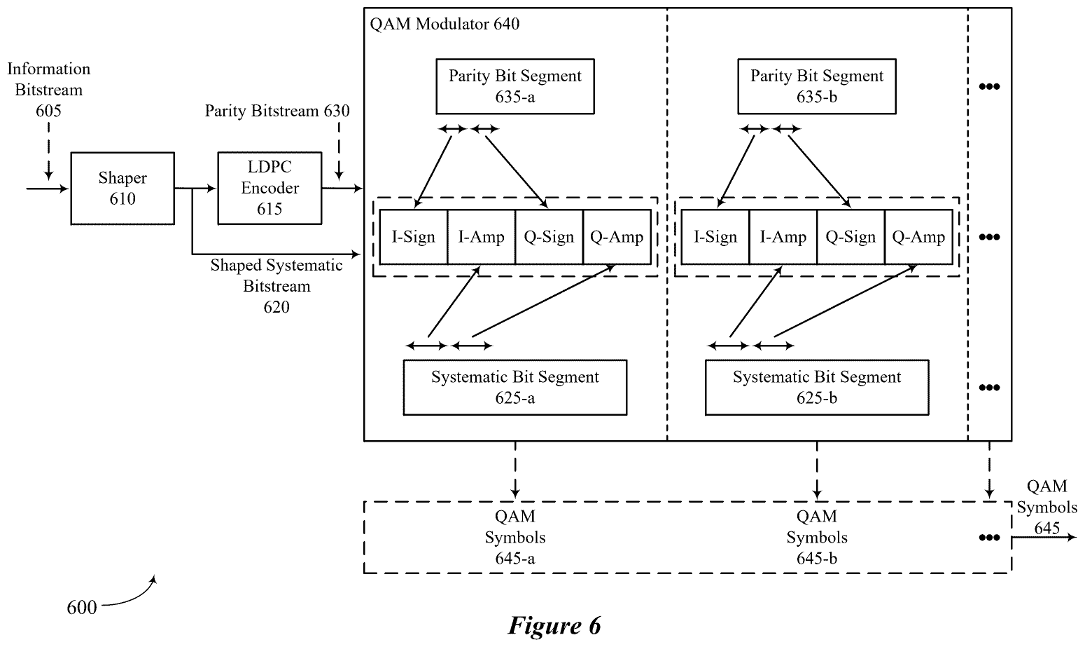

As such, the QAM modulator 240 may receive the parity bitstream 230 (e.g., and repetition bits) as a first stream of bits and the shaped systematic bitstream 220 as a second stream of bits. In other words, the QAM modulator 240 may receive two separate inputs (e.g., rather than one serially concatenated input). Receiving the shaped systematic bitstream 220 as a separate stream of bits may enable the QAM modulator 240 to maintain the structure of the shaped systematic bitstream 220, which may result in the frequency usage of the constellation points (e.g., of the given QAM modulation order associated with the QAM modulator 240) to be probabilistically shaped to be non-uniform, as described further with reference to FIG. 5 and FIG. 6.

Thus, the QAM modulator 240 may output one or more QAM symbols 245 and the transmitter 200 (e.g., or another component of the transmitter 200) may map the one or more QAM symbols 245 to one or more subcarriers of one or more OFDM symbols to be transmitted by the transmitter 200. The transmitter 200 may then transmit a signal associated with the one or more QAM symbols 245, where the signal is associated with a Gaussian distribution of energy based on the non-uniform probabilistically shaping of the constellation points at the QAM modulator 240.

FIGS. 3A and 3B show examples of transmitters 300 (e.g., a transmitter 300-a and a transmitter 300-b) that supports techniques for probabilistic constellation shaping in Wi-Fi systems. According to some aspects, the transmitters 300 may be part of a WLAN such as a Wi-Fi network (e.g., system). For example, the transmitters 300 may support at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11bc, 802.11bf, and 802.11bn).

In some wireless communications systems, such as the Wi-Fi network, wireless devices (e.g., transmitters 300 and receivers), such as APs 102 and STAs 104, may support the use of various MCSs to transmit and receive data so as to take advantage of wireless channel conditions, for example, to increase throughput, reduce latency, or enforce various QoS parameters. For example, existing technology (such as IEEE 802.11ax standard amendment protocols) supports the use of QAM in which a bitstream may be input into a QAM modulator 340 to form QAM symbols 345, which may be mapped to subcarriers of one or more orthogonal frequency-division OFDM symbol for transmission (e.g., using multiple spatial streams, Nₛₛ≥2).

In such cases (e.g., Nₛₛ≥2), an encoder, such as an LDPC encoder 315, of a transmitting wireless device may receive an information bitstream 305, may generate a systematic bitstream correspond to the information bitstream 305, and may encode (e.g., and rate match) the information bitstream 305 to generate a parity bitstream 330 (e.g., and repetition bits), where the parity bitstream 330 is based on the information bitstream 305. A serializer (e.g., of the transmitting wireless device) at an output of the LDPC encoder 315 may receive the systematic bitstream and the parity bitstream 330 and may construct one or more LDPC codewords (e.g., codeword grouping), where each LDPC codeword includes a group of systematic bits (e.g., from the systematic bitstream), which may be referred to as a systematic bit segment, appended with a group of parity bits 330 (e.g., from the parity bitstream 330), which may be referred to as a parity bit segment. In such cases, the one or more LDPC codewords may form a single, serialized bitstream to be fed to a stream parser 350 to further be fed to one or more QAM modulators 340.

Thus, for multiple spatial stream (e.g., Nₛₛ≥2), the stream parser 350 may form groupings of bits (e.g., of the serialized bitstream) to distribute (e.g., in a round robin fashion) to multiple QAM modulators 340, where each of the QAM modulators 340 is associated with a spatial stream of the multiple spatial stream. In other words, each QAM modulator 340 of the multiple QAM modulators 340 may receive multiple groupings of bits (e.g., chunks of bit), such that each QAM modulator 340 receives a portion of the serialized bitstream. In some cases (e.g., equal modulation MIMO), each grouping of bits may include N_{qam}/2 bits, where N_{qam} may be a quantity of bits used to form a QAM symbol 345, such that each grouping of bits received by a QAM modulator 340 may be either an ‘I’ portion (e.g., In-phase component) or a ‘Q’ portion (e.g., Quadrature component) of a QAM symbol 345. In some other cases (e.g., unequal modulation MIMO), groupings of bits fed to each QAM modulator 340 may not be the same based on modulation orders across the multiple spatial streams being different. For example, each grouping of bits fed to a first QAM modulator 340 may include N_{qam,1}/2 bit and each grouping of bits fed to a second QAM modulator 340 may include N_{qam,2}/2 bit, where N_{qam,1}/2 may be a first quantity of bits used to form a QAM symbol 345 of a first modulation order associated with the first QAM modulator 340 (e.g., for a first spatial stream) and N_{qam,2}/2 may be a second quantity of bits used to form a QAM symbol 345 of a second modulation order associated with the second QAM modulator 340 (e.g., for a second spatial stream). In either case, each QAM modulator 340 of the multiple QAM modulators 340 may perform modulation separately, based on a respective portion of the serialized bitstream received by the QAM modulator 340, to generate a respective set of QAM symbols 345 for an associated spatial stream of the multiple spatial streams.

As described previously, with reference to FIG. 2, in some cases, a transmitting wireless device may perform constellation shaping on an information bitstream 305, such that the constellation (e.g., associated with the QAM modulator 340) may be associated with a non-uniform distribution in which constellation points of the constellation are associated with variable usage frequencies. To support constellation shaping, the transmitting wireless device may include a shaper 310 prior to the LDPC encoder 315 to shape the information bitstream 305 into a shaped systematic bitstream 320 (e.g., corresponding to the information bitstream 305), such that values (e.g., 0 or 1) of each shaped systematic bit of the shaped systematic bitstream 320 may not be equally likely (e.g., may be associated with a non-uniform distribution) which may result in a non-uniform distribution of a constellation associated with a QAM modulator 340. In such cases, the non-uniform distribution may be based on a structure of the shaped systematic bitstream 320 (e.g., the structure of the set of shape systematic bits may be based on the shaping). According to existing transmitting wireless devices, as described previously, the transmitting wireless device may encode the shaped systematic bitstream 320 to generate a parity bitstream 330 (e.g., set of parity bits and repetition bits), where the parity bitstream 330 is based on the shaped systematic bitstream 320. The serializer at the output of the LDPC encoder 315 may receive the shaped systematic bitstream 320 and the parity bitstream 330 and may construct a serialized bitstream of one or more LDPC codewords, where each LDPC codeword includes a shaped systematic bit segment (e.g., of the shaped systematic bitstream) appended with a parity bit segment (e.g., of the parity bitstream).

Thus, the stream parser 350 may distribute the serialized bitstream across the multiple QAM modulators 340 and each QAM modulator 340 may generate one or more QAM symbols 345 based on a received portion of the serialized bitstream. However, as described with reference to FIG. 2, each QAM modulator 340 may receive a single input (e.g., a portion of the single serialized bitstream) and generating one or more QAM symbols 345 based on the single input may negate the shaping performed by the shaper 310. That is, each QAM modulator 340 receiving shaped systematic bits as part of a portion of the single serialized bitstream may result in the QAM modulator 340 not accounting for the structure of shaped systematic bits, such that the non-uniform distribution (e.g., intended by the shaper 310) may not occur. In other words, mapping of the bits of the portion of the single serialized bitstream to constellation points may result in an unintended non-uniform distribution that may not result in a Gaussian distribution of energy.

Accordingly, techniques described herein may enable a transmitting wireless device, such as the transmitters 300, to support constellation shaping. In particular, the transmitter 300 may support constellation shaping for multiple spatial stream (e.g., Nₛₛ≥2). For example, as described with reference to FIGS. 3A and 3B, a shaper 310 may receive an information bitstream 305 (e.g., set of information bits) and may shape (e.g., alter) bits of the information bitstream 305 into a shaped systematic bitstream 320 such that, by the end of a QAM modulation process (e.g., at one or more QAM modulators 340), a frequency usage of constellation points (e.g., of a given QAM modulation order associated with each QAM modulator 340) may be probabilistically shaped to be non-uniform (e.g., be associated with a non-uniform distribution). Thus, the shaper 310 may output a shaped systematic bitstream 320 associated with a given structure (e.g., based on the shaping), where the shaped systematic bitstream 320 may correspond to the information bitstream 305. In such cases, structure may be generated such that shaped systematic bits of the shaped systematic bitstream 320 may not be altered and the shaped systematic bitstream 320 may not be segmented or broken up. An LDPC encoder 315 (e.g., and rate matcher) may receive the shaped systematic bitstream 320 from the shaper 310 and may generate a parity bitstream 330 (e.g., and repetition bits) based on the shaped systematic bitstream 320.

In some cases, as depicted in FIG. 3A, a single QAM modulator 340-a (e.g., of the transmitter 300-a) may receive the parity bitstream 330 (e.g., and repetition bits) as a first stream of bits and the shaped systematic bitstream 320 as a second stream of bits. In other words, the QAM modulator 340-a may receive two separate inputs (e.g., rather than one serially concatenated input). Receiving the shaped systematic bitstream 320 as a separate stream of bits may enable the QAM modulator 340 to maintain the structure of the shaped systematic bitstream 320, which may result in the frequency usage of the constellation points (e.g., of the given QAM modulation order associated with the QAM modulator 340) to be probabilistically shaped to be non-uniform, as described further with reference to FIG. 5 and FIG. 6. Thus, the QAM modulator 340-a may generate multiple QAM symbols 345 based on the parity bitstream 330 (e.g., and repetition bits) and the shaped systematic bitstream 320. Additionally, to support multiple spatial streams, a stream parser 350-a may distribute the multiple QAM symbols 345 across the multiple spatial streams. In such cases, the stream parser 350-a may distribute the multiple QAM symbols 345 one at a time in a round-robin fashion across the multiple spatial streams (e.g., until all of the multiple QAM symbols 345 have been distributed). That is, the stream parser 350-a may distribute a first QAM symbol 345 to a first spatial stream of the multiple spatial streams, a second QAM symbol 345 to a second spatial stream of the multiple spatial streams, and so on until a last spatial stream of the multiple spatial streams, at which point, the stream parser 350-a may return to the first spatial stream to repeat the distribution cycle. For example, as depicted in FIG. 3A, 2 spatial streams may exist, such that the stream parser 350-a may distribute one or more QAM symbols 345-a for a first spatial stream and one or more QAM symbols 345-b for a second spatial stream, where the multiple QAM symbols 345 include the one or more QAM symbols 345-a and the one or more QAM symbols 345-b. Additionally, for each set of QAM symbols 345 (e.g., the one or more QAM symbols 345-a and the one or more QAM symbols 345-b), the transmitter 300-a (e.g., another component of the transmitter 300-a) may map the set of QAM symbols 345 to a respective spatial stream of one or more subcarriers of one or more OFDM symbols be transmitted by the transmitter 300-a via a respective spatial stream.

In some other cases, as depicted in FIG. 3B, parsing (e.g., bitstream parsing) may occur prior to modulation. That is, the transmitter 300-b may include two stream parsers 350, including a parity bitstream parser 350-b and a systematic bitstream parser 350-c. That is, the parity bitstream parser 350-b may receive the parity bitstream 330 and may distribute the parity bitstream 330 across multiple QAM modulators 340 (e.g., until all parity bits 330 of the parity bitstream 330 have been distributed), where each QAM modulator 340 is associated with a spatial stream of the multiple spatial streams (e.g., QAM modulation may be performed independently for each spatial stream). Similarly, the systematic bitstream parser 350-c may receive the shaped systematic bitstream 320 and may distribute the shaped systematic bitstream 320 across the multiple QAM modulators 340 (e.g., until all shaped systematic bits of the shaped systematic bitstream 320 have been distributed). In such cases, the parity bitstream parser 350-b may distribute 1 bit to each of the QAM modulators 340 (e.g., of the multiple QAM modulators 340) in a round-robin fashion and the systematic bitstream parser 350-c may distribute (N_{qam}−2)/2 bit tuples to each of the QAM modulators 340 (e.g., of the multiple QAM modulators 340) in a round-robin fashion, where N_{qam} may represent a number of bits per QAM symbol 345 of a modulation order associated with (e.g., used by) the multiple QAM modulators 340. Thus, each QAM modulator 340 of the multiple QAM modulators 340 may generate one or more QAM symbols 345 to be put on a respective spatial stream of one or more subcarriers in one or more OFDM symbols to be transmitted. For example, as depicted in FIG. 3B, 2 spatial streams may exist, such that the parity bitstream parser 350-b may distribute the parity bitstream 330 to a QAM modulator 340-b and a QAM modulator 340-c, and the systematic bitstream parser 350-c may distribute the shaped systematic bitstream 320 to the QAM modulator 340-b and the QAM modulator 340-c. Thus, the QAM modulator 340-b may generate one or more QAM symbols 345-c for a first spatial stream and the QAM modulator 340-c may generate one or more QAM symbols 345-d for a second spatial stream.

Though FIGS. 3A and 3B may be described in the context of 2 spatial streams, this is not to be regarded as a limitation of the present disclosure. In this regard, techniques described herein may support any quantity of spatial streams.

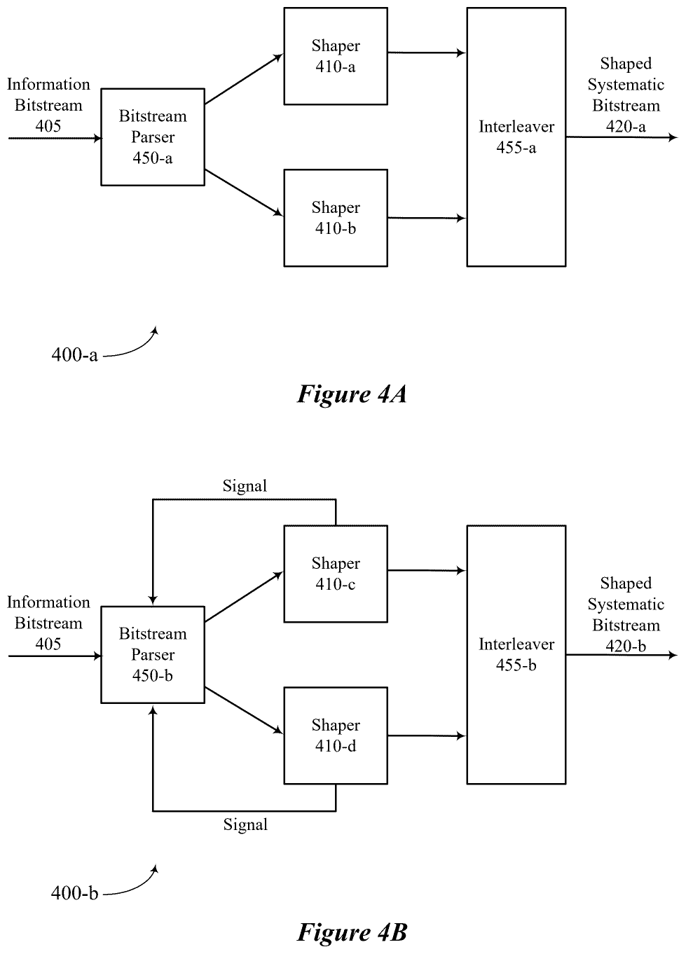

FIGS. 4A and 4B show examples of bitstream parsing schemes 400 (e.g., a bitstream parsing scheme 400-a and a bitstream parsing scheme 400-b) that supports techniques for probabilistic constellation shaping in Wi-Fi systems. According to some aspects, the bitstream parsing schemes 400 may be implemented by wireless devices (e.g., transmitters) of a WLAN such as a Wi-Fi network (e.g., system). For example, the wireless devices may support at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11be, 802.11bf, and 802.11bn).

In some examples, as described with reference to FIGS. 3A and 3B, a transmitter may support multiple spatial streams, where the multiple spatial streams are associated with a same QAM modulation order (e.g., equal modulation). In some other examples, a transmitter may support multiple spatial streams, where the multiple spatial streams are associated with (e.g., carry) a different QAM modulation orders such that each spatial stream may be associated with an independent shaper 410 prior to combined LDPC encoding (e.g., unequal modulation). To feed each shaper 410 with information bits from an information bitstream 405, a prior step (e.g., prior to the combined LDPC encoding) of information bitstream parsing may occur.

According to the bitstream parsing scheme 400-a, depicted in FIG. 4A, a bitstream parser 450-a may distribute (e.g., send) a group of information bits (e.g., tuple, chunk, increment) associated with a respective fixed group size (e.g., fixed quantity of bits in each group of bits) to each shaper 410 of multiple shapers 410 in a round-robin fashion, where each shaper 410 of the multiple shapers 410 is associated with a spatial stream of the multiple spatial streams. That is, each shaper 410 may be associated with a respective fixed group size, such that the bitstream parser 450-a distributes bits to a given shaper 410 in groups of the fixed group size specific to that shaper 410. In some cases, the shapers 410 may be associated with a same fixed group size while, in some other cases, the shapers 410 may be associated with different fixed group sizes. For example, a fixed ratio of bits may be parsed to each shaper 410.

For example, as depicted in FIG. 4A, the transmitter may support 2 spatial streams, such that the bitstream parser 450-a may distribute groups of bits from the information bitstream 405 to each of a shaper 410-a associated with a first spatial stream and a shaper 410-b associated with a second spatial stream. In some cases, the shaper 410-a and the shaper 410-b may be associated with a same fixed group size. In such cases, the bitstream parser 450 may distribute a first group of information bits (e.g., from the information bitstream 405) of the same fixed group size (e.g., tuple, increment, etc.) to the shaper 410-a, may distribute a second group of information bits (e.g., from the information bitstream 405) of the same fixed group size to the shaper 410-b, and may repeat the distribution process (e.g., in the round-robin fashion) until all information bits of the information bitstream 405 are distributed. In some other cases, the shaper 410-a and the shaper 410-b may be associated with different fixed group sizes, such that the shaper 410-a is associated with a first fixed group size and the shaper 410-b is associated with a second fixed group size. In such cases, the bitstream parser 450 may distribute a first group of information bits (e.g., from the information bitstream 405) of the first fixed group size to the shaper 410-a, may distribute a second group of information bits (e.g., from the information bitstream 405) of the second fixed group size to the shaper 410-b, and may repeat the distribution process (e.g., in the round-robin fashion) until all information bits of the information bitstream 405 are distributed.

In some cases, a fixed group size associated with a shaper 410 may be a function of a QAM modulation order of an associated spatial stream, a function of a ratio of the associated spatial stream's bits-per-QAM order to a sum of bits-per-QAM orders of all other spatial streams, a function of a shaping rate of the shaper 410 (e.g., of the associated spatial stream, a function of the shaping rate of the shaper 410 and shaping rates of one or mor, or all, other shapers 410 (e.g., all other spatial streams), or any combination thereof. Thus, each shaper 410 may generate outputs in groups of information bits, or increments, (e.g., shaped pulse-amplitude modulation (PAM) amplitude tuple of bits) and an interleaver 455-a may combine the outputs across the shapers 410 to produce a shaped systematic bitstream 420-a, where each group of information bits may not be broken up by the interleaver 455-a (e.g., the interleaver 455-a may treat each group of information bits as an atomic set). For example, the shaper 410-a may provide 3-bit groups (e.g., chunks) and the shaper 410-b may produce 4-bit groups, such that the interleaver 455-a may concatenate a serial output of information bits starting with a 3-bit group from the shaper 410-a, follow by a 4-bit group from the shaper 410-b, followed by a next 3-bit group from the shaper 410-a, followed by a next 4-bit group from the shaper 410-b, and so on, until all bits have been received from the shapers 410. Thus, the interleaved bitstream may include (e.g., be) shaped systematic bits that may be a systematic part of an LDPC encoder (e.g., a shaped systematic bitstream 320). In other words, the interleaver 455-a may output the shaped systematic bitstream 420-a.

According to the bitstream parsing scheme 400-b (e.g., considering some shaper designs, such as Huffman table, or prefix encoding, approaches), depicted in FIG. 4B, shapers 410, such as a shaper 410-c and a shaper 410-d, may generate output information bit groups of a fixed size (e.g., group of bits or chunk) based on a variable quantity of input bits. That is, each shaper 410 may receive a different (e.g., variable) quantity of input information bits but may output a same (e.g., equal) quantity of output information bits. In some cases, the bitstream parsing scheme 400-b may be based on a ratio of a total quantity of output information bits across all shapers 410 relative to a total quantity of input information bits across all shapers 410. Thus, a bitstream parser 450-b may distribute information bits of an information bitstream 405 in a manner such that the bitstream parser 450-b may cycle through each of the shapers 410 in a round robin fashion while feeding (e.g., distributing bits to) a variable quantity of information bits to each shaper 410. Thus, when being fed (e.g., when receiving bits), a shaper 410 may send a signal back to the bitstream parser based on (e.g., when it has) finished generating an output information bit group (e.g., of a fixed size specific to the shaper 410). The signal may indicate to the bitstream parser 450-b to stop feeding (e.g., distributing bits to) the shaper 410 associated with the signal and move on to feed a shaper 410 associated with a next spatial stream (e.g., until all bits of the information bitstream 405 have been distributed). An interleaver 455-b may combine the outputs across the shapers 410 in a manner similar to the bitstream parsing scheme 400-a, where each group of information bits may not be broken up by the interleaver 455-b. Thus, the interleaver 455-a may output shaped systematic bitstream 420-b.

In either case (e.g., the bitstream parsing scheme 400-a and the the bitstream parsing scheme 400-b), spatial stream parsing (e.g., for unequal modulation) performed after the bitstream parsing may be similar to spatial stream parsing depicted in FIGS. 3A and 3B (e.g., for equal modulation). That is, rather than an LDPC encoder 315 (e.g., in either of the transmitter 300-a or the transmitter 300-b) receiving a shaped systematic bitstream 320 from a shaper 310, the LDPC encoder 315 may receive a shaped systematic bitstream 420 (e.g., set of shaped systematic bits) from an interleaver 455. However, for the transmitter 300-a (e.g., parsing after modulation), QAM modulation orders of QAM symbols 345 in a stream of QAM symbols 345 from the QAM modulator 340-a may be patterned such that the stream parser 350-a may correctly send correct QAM symbols 345 to corresponding spatial streams through round-robin distribution. That is, a set of information bits of the information bitstream 405 may be shaped based on a spatial stream associated with a shaper 410 through which the set of information bits are fed, such that QAM symbols 345 including the set of information bits may be (e.g., should be) parsed (e.g., by the stream parser 350-a) to the spatial stream associated with the shaper 410 through which the set of information bits were fed.

Though FIGS. 4A and 4B may be described in the context of 2 spatial streams, this is not to be regarded as a limitation of the present disclosure. In this regard, techniques described herein may support any quantity of spatial streams.

FIG. 5 shows an example of a modulation scheme 500 that supports techniques for probabilistic constellation shaping in Wi-Fi systems. According to some aspects, the modulation scheme 500 may be implemented by wireless devices (e.g., transmitters) of a WLAN such as a Wi-Fi network (e.g., system). For example, the wireless devices may support at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11be, 802.11bf, and 802.11bn).

As described previously, with reference to FIG. 2, existing transmitters may support a QAM modulator 540 that receives a single serialized bitstream (e.g., single input) including multiple LDPC codewords, where each LDPC codeword includes a parity bit segment 535 (e.g., including repetition bits) and a systematic bit segment 525. Thus, modulation may be performed by the QAM modulator 540 without regards to what type of bit is being modulated and blindly taking N_{qam} bits at a time to form QAM symbols 545, where N_{qam} may represent a number of bits per QAM symbol 545 of a modulation order associated with (e.g., used by) the QAM modulators 540.

However, as described previously, constellating shaping works in a system by a shaper 510 forming output information bit groups (e.g., tuples) that represent (e.g., and will map to) I component or Q component (i.e. PAM) amplitudes of QAM symbols 545, where the amplitude values are associated with a desired distribution (e.g., as shaped by the shaper 510). This method of shaping to PAM amplitudes may be used because it may pair directly with LDPC encoding, where LDPC may be a so-called systematic code in that the input into an LDPC encoder 515 to may appear directly in an output codeword (e.g., LDPC codeword) with no modification. Thus, LDPC encoders 515 may preserve the input bits and arranged group structure coming out of the shaper 510 as a shaped systematic bitstream 520 (e.g., set of shaped systematic bits). In such cases, a parity bitstream 530 generated by the LDPC encoder 515 may not be considered shaped and can be assumed to be equiprobable 0s and 1s. Thus, QAM modulators 540 of existing transmitters that blindly take N_{qam} bits at a time to form QAM symbols 545 may not consider the arranged group structure and, as such, may not form the desired distribution.

Accordingly, techniques described herein may enable a QAM modulator 540 to consider the arranged group structure to form constellation shaped QAM symbols 545. For example, a constellation shaped QAM symbol 545 may be formed by using shaped systematic bit groups to form I and Q component amplitudes for the QAM symbol 545, and then using parity bits as signs for the I and Q components for the QAM symbol 545. Thus, the shaper 510 upstream may be generating bit group outputs (e.g., shaped systematic bit tuples), such that energy of the resulting set of QAM symbols 545 from all information bits of an information bitstream 505, when taken together, form a Gaussian-like distribution. In some cases, energy of a QAM symbol 545 may not depend on a polarity (i.e., sign) of the QAM symbol 545 and may depend on I and Q component amplitudes for the QAM symbol 545.

Thus, to use shaped systematic bit groups to form I and Q component amplitudes for the QAM symbol 545 and use parity bits to form signs for the I and Q components for the QAM symbol 545, a transmitter may receive separate streams of parity bits and shaped systematic bits, as described with reference to FIG. 2, FIG. 3A, and FIG. 3B, and may employ the modulation scheme 500, as described with reference to FIGS. 5, the modulation scheme 600, as described with reference to FIG. 6, or both.

According to the modulation scheme 500, a QAM modulator 540 may generate QAM symbols 545 without regard to LDPC codeword boundaries in the shaped systematic bits and the parity bits (e.g., and repetition bits). That is, as described previously with reference to FIG. 2, FIG. 3A, and FIG. 3B, a shaper 510 may receive an information bitstream 505 and shape the information bits of the information bitstream 505 to produce a shaped systematic bitstream 520. An LDPC encoder 515 may then receive the shaped systematic bitstream 520 and generate a parity bitstream 530 (e.g., parity bitstream) based on the shaped systematic bitstream 520.

Thus, the LDPC encoder 515 may produce ‘N’ LDPC codewords from the shaped systematic bitstream 520 (e.g., information bitstream 505 post shaping) according to an encoding rate ‘R,’ where each LDPC codeword includes a systematic bit segment 525 (e.g., subset of bits from the shaped systematic bitstream 520) and a parity bit segment 535 (e.g., subset of bits from the parity bitstream 530). For example, a first LDPC codeword may include a parity bit segment 535-a and a systematic bit segment 525-a, and a second LDPC codeword may include a parity bit segment 535-b and a systematic bit segment 525-b. The QAM modulator 540 may receive the parity bitstream 530 (e.g., parity bit bitstream) and the shaped systematic bitstream 520 (e.g., shaped systematic bitstream) and may direct them to two separate queues. A first queue, which may be referred to as a parity queue, may include the parity bits (e.g., and repetition bits) of all LDPC codewords (e.g., the parity bitstream), arrange serially, and a second queue, which may be referred to as a systematic queue, may include the shaped systematic bits of all LDPC codewords (e.g., the shaped systematic bitstream 520), arrange serially. Bits of LDPC codewords (e.g., shaped systematic bits and parity bits) may be referred to as coded bits of the LDPC codewords.

The QAM modulator 540 may then generate (e.g., form) QAM symbols 545 for the ‘N’ LDPC codewords according to two phases (e.g., if needed). In some cases (e.g., equal modulation MIMO), in a first phase, the QAM modulator 540 may start at a beginning of each queue and form a QAM symbols 545-a by consuming bits from the queues as follows:
1. Draw (e.g., pull, map) 1 bit from the parity bit queue (e.g., regardless of associated LDPC codeword) to be a sign of an I-component (e.g., I-sign) of a QAM symbol 545-a.
2. Draw (N_{qam}−2)/2 bits from the systematic queue (e.g., regardless of associated LDPC codeword) to be an amplitude of the I-component (e.g., I-amp) of the QAM symbol 545-a.
3. Draw a next (e.g., subsequent) 1 bit from the parity bit queue (e.g., regardless of associated LDPC codeword) to be a sign of a Q-component (e.g., Q-sign) of the QAM symbol 545-a.
4. Draw a next (N_{qam}−2)/2 bits from the systematic queue (e.g., regardless of associated LDPC codeword) to be an amplitude of the Q-component (e.g., Q-amp) of the QAM symbol 545-a.

The QAM symbol 545-a may be a first QAM symbol to be output by the QAM modulator 540, such that steps 1 through 4 may be repeated one or more times if there are sufficient bits in each queue to complete a QAM symbol 545 (e.g., for equal modulation MIMO). That is, the QAM modulator 540 may repeat steps 1 through 4 until either the parity queue, the systematic queue, or both, run out of bits to complete a QAM symbol 545 (e.g., the parity queue has less than 2 bits, the systematic queue has less than N_{qam}−2 bits). In some cases, all bits may be consumed from both of the parity queue and the systematic, such that the QAM modulator 540 may complete modulation (e.g., without moving to phase 2). In some other cases, either the parity queue, the systematic queue, or both, may include remaining bits, where a QAM symbol 545 may not be formed using the remaining bits, such that the QAM modulator 540 may move to a second phase of modulation.

In some cases, the QAM modulator 540 may not be able to form a QAM symbol 545 based on the parity queue not having enough bits

$$( e . g . , when \frac{R}{1 - R} > \frac{{N}_{q a m} - 2}{2} ) .$$

In such cases, the QAM modulator 540 may complete the second phase of modulation according to the following steps:
1. The QAM modulator 540 may calculate a location ‘X’ in the systematic queue according to the following Equation 1 (e.g., assuming zero-indexing of the queues):

$$X = {N}_{qs , total} \times ( {N}_{qam} - 2 )$$

$${N}_{qs , total} = ⌈ \frac{{N}_{avbits}}{{N}_{QAM}} ⌉ , a total quantity of QAM symbols 545 to \\ \\ \\ be generated from coded bit of all of the LDPC codewords$$

$${N}_{QAM} = a total quantity of the coded bits of all of the LDPC codewords$$

$${N}_{avbits} = a total number of bits per QAM symbol \\ \\ \\ 545 in a single spatial stream and equal modulation MIMO$$

2. The QAM modulator 540 may move a portion of the systematic queue from location ‘X’ until an end of the systematic queue to be an extension of the parity queue (e.g., and removed from the systematic queue).
3. The QAM modulator 540 may continue forming QAM symbols 545 with sign bits (e.g., bits for I-Sign and Q-Sign) being drawn from the extension to the parity queue and amplitude bits (e.g., bits for I-Amp and Q-Amp) being drawn from the truncated systematic queue.
4. Once no more QAM symbols 545 may be fully formed (e.g., including complete I and Q components) due to either the end of the extended parity queue or the truncated systematic queue being reached, the QAM modulator 540 may insert pad bits to complete a last QAM symbol 545 (e.g., if necessary) and may finish QAM modulation of a payload (e.g., the information bitstream 505).

In some other cases, the QAM modulator 540 may not be able to form a QAM symbol 545 based on the systematic queue not having enough bits

$$( e . g . , when \frac{R}{1 - R} < \frac{{N}_{q a m} - 2}{2} ) .$$

In such cases, the QAM modulator 540 may complete the second phase of modulation according to the following steps:
1. The QAM modulator 540 may calculate a location ‘Y’ in the parity queue according to the following Equation 2 (e.g., assuming zero-indexing of the queues):

$$Y = {N}_{qs , total} \times 2 \qquad ( 2 )$$

2. The QAM modulator 540 may move a portion of the parity queue from location ‘Y’ until an end of the parity queue to be an extension of the systematic queue (e.g., and removed from the parity queue).
3. The QAM modulator 540 may continue forming QAM symbols 545 with sign bits (e.g., bits for I-Sign and Q-Sign) being drawn from the truncated parity queue and amplitude bits (e.g., bits for I-Amp and Q-Amp) being drawn from the extension of the systematic queue.
4. Once no more QAM symbols 545 may be fully formed (e.g., including complete I and Q components) due to either the end of the truncated parity queue or the extended systematic queue being reached, the QAM modulator 540 may insert pad bits to complete a last QAM symbol 545 (e.g., if necessary) and may finish QAM modulation of a payload (e.g., the information bitstream 505).

In some cases (e.g., unequal modulation MIMO), the QAM modulator 540 may use a different quantity of bits from the systematic queue (e.g., systematic bitstream) for each QAM symbol 545 (e.g., at least one of the QAM symbols 545 generated by the QAM modulator 540). In such cases, as the QAM modulator 540 is consumes (e.g., uses) bits from the systematic queue, the QAM modulator 540 may track what QAM modulation order amplitude it may produce for a given QAM symbol 545 based on a position in the systematic queue (e.g., systematic bitstream) and a previous amplitude produced by the QAM modulator 540 for a previous QAM symbol 545.

For example, in a first phase, the QAM modulator 540 may start at a beginning of each queue and form a QAM symbols 545-a by consuming bits from the queues as follows:
1. Draw (e.g., pull, map) 1 bit from the parity bit queue to be a sign of an I-component (e.g., I-sign) of a QAM symbol 545-a.
2. Draw a first quantity of bits from the systematic queue to be an amplitude of the I-component (e.g., I-amp) of the QAM symbol 545-a, where the first quantity may be based on a first QAM modulation order associated with a first spatial stream (e.g., with a spatial stream index, ‘ss_{idx},’ of 0).
3. Draw a next (e.g., subsequent) 1 bit from the parity bit queue to be a sign of a Q-component (e.g., Q-sign) of the QAM symbol 545-a.
4. Draw the first quantity of bits from the systematic queue to be an amplitude of the Q-component (e.g., Q-amp) of the QAM symbol 545-a.

The QAM symbol 545-a may be a first QAM symbol 545 to be output by the QAM modulator 540, such that steps 1 through 4 may be repeated one or more times if there are sufficient bits in each queue to complete a QAM symbol, where a quantity of bits drawn for an amplitude of an I component and a Q component of a QAM symbol 545 may be variable during each repetition and may depend on a QAM modulation order associated with a respective spatial stream. For example, steps 1 through 4 may be repeated for a QAM symbol 545-b (e.g., not depicted), where the first quantity is updated to a second quantity associated with a second QAM modulation order further associated with a second spatial stream (e.g., with a spatial stream index, ‘ss_{idx},’ of 1). The QAM modulator 540 may continue this repetition process until a QAM symbol 545 associated with a last spatial stream (e.g., with a spatial stream index, ‘ss_{idx},’ of Nₛₛ), after which the QAM modulator 540 may loop back to producing a QAM symbol 545 for the first spatial stream and continue to loop in this round-robin fashion until either the systematic queue, the parity queue, or both, run out of bits.

Though depicted in the context of a single spatial stream, this is not to be regarded as a limitation of the present disclosure. In this regard, techniques described herein, specifically with reference to FIG. 5, may be applied to any quantity of spatial streams.

FIG. 6 shows an example of a modulation scheme 600 that supports techniques for probabilistic constellation shaping in Wi-Fi systems. According to some aspects, the modulation scheme 600 may be implemented by wireless devices (e.g., transmitters) of a WLAN such as a Wi-Fi network (e.g., system). For example, the wireless devices may support at least one of the IEEE 802.11 family of wireless communication protocol standards (such as defined by the IEEE 802.11-2020 specification or amendments thereof including, but not limited to, 802.11ay, 802.11ax, 802.11az, 802.11ba, 802.11bc, 802.11bd, 802.11be, 802.11bf, and 802.11bn).

As described with reference to FIG. 2, to use shaped systematic bit groups to form I and Q component amplitudes for QAM symbol 645 and use parity bits to form signs for the I and Q components for the QAM symbol 645, a transmitter may receive separate streams of parity bits and shaped systematic bits, as described with reference to FIG. 2, FIG. 3A, and FIG. 3B, and may employ the modulation scheme 500, as described with reference to FIG. 5, the modulation scheme 600, as described with reference to FIG. 6, or both.

According to the modulation scheme 600, a QAM modulator 640 may generate QAM symbols 645 with regard to LDPC codeword boundaries in a shaped systematic bitstream 620 and a parity bitstream 630 (e.g., and repetition bits) That is, the QAM modulator 640 may modulate all bits from an LDPC codeword before moving to a next LDPC codeword, which may reduce buffering thresholds (e.g., requirements) at a receiver (e.g., as compared to the modulation scheme 500). For example, as described previously with reference to FIG. 2, FIG. 3A, and FIG. 3B, a shaper 610 may receive an information bitstream 605 and shaped the bits of the information bitstream to produce a shaped systematic bitstream 620. An LDPC encoder 615 may then receive the shaped systematic bitstream 620 and generate a parity bitstream 630 (e.g., parity bitstream) based on the shaped systematic bitstream 620.

Thus, the LDPC encoder 615 may produce ‘N’ LDPC codewords from the shaped systematic bitstream 620 (e.g., information bitstream 605 post shaping) according to an encoding rate ‘R,’ where each LDPC codeword includes a systematic bit segment 625 (e.g., subset of bits from the shaped systematic bitstream 620) and a parity bit segment 635 (e.g., subset of bits from the parity bitstream 630). For example, a first LDPC codeword may include a parity bit segment 635-a and a systematic bit segment 625-a, and a second LDPC codeword may include a parity bit segment 635-b and a systematic bit segment 625-b. The QAM modulator 640 may receive the parity bitstream 630 (e.g., parity bit bitstream) and the shaped systematic bitstream 620 (e.g., shaped systematic bitstream) and may direct them to two separate queues. A first queue, which may be referred to as a parity queue, may include the parity bits (e.g., and repetition bits) of all LDPC codewords (e.g., the parity bitstream 630), arrange serially, and a second queue, which may be referred to as a systematic queue, may include the shaped systematic bits of all LDPC codewords (e.g., the shaped systematic bitstream 620), arrange serially.

The QAM modulator 640 may then generate (e.g., form) QAM symbols 645 for the ‘N’ LDPC codewords according to two phases. In some cases (e.g., equal modulation MIMO), in a first phase, the QAM modulator 640 may start at a beginning of each queue and form a QAM symbols 645-a by consuming bits from the queues as follows:
1. Draw (e.g., pull, map) 1 bit (e.g., associated with the first LDPC codeword) from the parity bit queue to be a sign of an I-component (e.g., I-sign) of a QAM symbol 645-a.
2. Draw (N_{qam}−2)/2 bits (e.g., associated with the first LDPC codeword) from the systematic queue to be an amplitude of the I-component (e.g., I-amp) of the QAM symbol 645-a.
3. Draw a next (e.g., subsequent) 1 bit bits (e.g., associated with the first LDPC codeword) from the parity bit queue to be a sign of a Q-component (e.g., Q-sign) of the QAM symbol 645-a.
4. Draw a next (N_{qam}−2)/2 bits f bits (e.g., associated with the first LDPC codeword) from the systematic queue to be an amplitude of the Q-component (e.g., Q-amp) of the QAM symbol 645-a.

The QAM symbol 645-a may be a first QAM symbol to be output by the QAM modulator 640, such that steps 1 through 4 may be repeated one or more times using bits associated with the first LDPC codeword from the queues if there are sufficient bits in associated with the first LDPC codeword each queue to complete a QAM symbol 645. That is, the QAM modulator 640 may repeat steps 1 through 4 until either the parity queue, the systematic queue, or both, run out of bits associated with the first LDPC codeword to complete a QAM symbol 645. In some cases, all bits associated with the first LDPC codeword may be consumed from both of the parity queue and the systematic, such that the QAM modulator 640 may complete modulation of the first LDPC codeword (e.g., without moving to phase 2) and may move on to modulation of the second LDPC codeword (e.g., following the same process using steps 1 through 4). In some other cases, either the parity queue, the systematic queue, or both, may include remaining bits associated with the first LDPC codeword, where a QAM symbol 645 may not be formed using the remaining bits associated with the first LDPC codeword, such that the QAM modulator 640 may move to a second phase of modulation before moving on to modulation of the second LDPC codeword. The QAM modulator 640 may repeat this process until all bits of all LDPC codewords have been used (e.g., all bits of the parity queue and the systematic queue have been used). Thus, the QAM modulator 640 may produce multiple sets of QAM symbols 645, such as a set of QAM symbols 645-a and a set of QAM symbols 645-b, where each set of QAM symbols is associated with an LDPC codeword and may be for subcarriers corresponding to the associated LDPC codeword.

Returning to the discussion of the second phase of modulation, in some cases, the QAM modulator 640 may not be able to form a QAM symbol 645 for a given LDPC codeword, such as the first LDPC codeword including the parity bit segment 635-a and the systematic bit segment 625-a) based on a parity sub-queue associated with the parity bit segment 635-a (e.g., a portion of the parity queue including parity bits from the parity bit segment 635-a) not having enough bits associated with the LDPC codeword

$$( e . g . , when \frac{R}{1 - R} > \frac{{N}_{q a m} - 2}{2} ) .$$

In such cases, the QAM modulator 640 may complete the second phase of modulation according to the following steps:
1. The QAM modulator 640 may calculate a location ‘X’ in a systematic sub-queue associated with the systematic bit segment 625-a (e.g., a portion of the systematic queue including shaped systematic bits from the systematic bit segment 625-a) according to the following Equation 3 (e.g., assuming zero-indexing of the queues):

$$X = {N}_{qs , {CW}_{N}} \times ( {N}_{qam} - 2 ) \qquad ( 3 )$$

$${N}_{qs , CW \_ N} = ⌈ \frac{{L}_{LDPC , {CW}_{N}}}{{N}_{QAM}} ⌋ , a total quantity of QAM symbols \\ \\ \\ 645 to be generated from the first LDPC codeword$$

$${N}_{QAM} = a total quantity of the coded bits of all LDPC of the codewords$$

$${L}_{LDPC , {CW}_{N}} = a length of the first codeword$$

2. The QAM modulator 640 may move a portion of the systematic sub-queue associated with the systematic bit segment 625-a from location ‘X’ until an end of the systematic sub-queue associated with the systematic bit segment 625-a to be an extension of the parity sub-queue associated with the parity bit segment 635-a.
3. The QAM modulator 640 may continue forming QAM symbols 645 with sign bits (e.g., bits for I-Sign and Q-Sign) being drawn from the extension to the parity sub-queue associated with the parity bit segment 635-a and amplitude bits (e.g., bits for I-Amp and Q-Amp) being drawn from the truncated systematic sub-queue associated with the systematic bit segment 625-a.
4. Once no more QAM symbols 645 may be fully formed (e.g., including complete I and Q components) due to either the end of the extended parity sub-queue associated with the parity bit segment 635-a or the truncated systematic sub-queue associated with the systematic bit segment 625-a, the QAM modulator 640 may insert pad bits to complete a last QAM symbol 645 (e.g., if necessary) and may finish QAM modulation of the first LDPC codeword, moving on to modulation of a second LDPC codeword.

In some other cases, the QAM modulator 640 may not be able to form a QAM symbol 645 based on the systematic sub-queue associated with the systematic bit segment 625-a

$$( e . g . , when \frac{R}{1 - R} < \frac{{N}_{q a m} - 2}{2} ) .$$

In such cases, the QAM modulator 640 may complete the second phase of modulation according to the following steps:
1. The QAM modulator 640 may calculate a location ‘Y’ in the parity sub-queue associated with the parity bit segment 635-a according to the following Equation 4 (e.g., assuming zero-indexing of the queues):

$$Y = {N}_{qs , CW \_ N} \times 2 \qquad ( 4 )$$

2. The QAM modulator 640 may move a portion of the parity sub-queue associated with the parity bit segment 635-a from location ‘Y’ until an end of the parity sub-queue associated with the parity bit segment 635-a to be an extension of the systematic sub-queue associated with the systematic bit segment 625-a.
3. The QAM modulator 640 may continue forming QAM symbols 645 with sign bits (e.g., bits for I-Sign and Q-Sign) being drawn from the truncated parity sub-queue associated with the parity bit segment 635-a and amplitude bits (e.g., bits for I-Amp and Q-Amp) being drawn from the extension to the systematic sub-queue associated with the systematic bit segment 625-a.
4. Once no more QAM symbols 645 may be fully formed (e.g., including complete I and Q components) due to either the end of the truncated parity sub-queue associated with the parity bit segment 635-a or the extended systematic sub-queue associated with the systematic bit segment 625-a, the QAM modulator 640 may insert pad bits to complete a last QAM symbol 645 (e.g., if necessary) and may finish QAM modulation of the first LDPC codeword, moving on to modulation of a second LDPC codeword.

In some cases (e.g., unequal modulation MIMO), the QAM modulator 640 may use a different quantity of bits from the systematic queue (e.g., systematic bitstream) for each QAM symbol 645 (e.g., at least one of the QAM symbols 645 generated by the QAM modulator 640). In such cases, as the QAM modulator 640 consumes (e.g., uses) bits from the systematic queue, the QAM modulator 540 may track what QAM modulation order amplitude it may produce for a given QAM symbol 645 based on a position in the systematic queue (e.g., systematic bitstream) and a previous amplitude produced by the QAM modulator 640 for a previous QAM symbol 645, as described with reference to FIG. 5. For example, the QAM modulator 640 may produce the I-amp then the Q-amp using an appropriate quantity of bits for QAM order of a first spatial stream (ss_idx=0), then I-amp and Q-amp using an appropriate quantity of bits for the QAM order of a second spatial stream (ss_idx=1), and so on until the QAM modulator 640 produces the I-amps and Q-amps for a last spatial stream (e.g., ss_idx=Nss). The QAM modulator 640 may then return back to producing I-amp and Q-amps for ss_idx=0 and loop in this round robin fashion. However, unlike the techniques for unequal modulation MIMO described with reference to FIG. 5, the generation of QAM symbols 645 for the spatial streams may be done for each LDPC codeword (e.g., with a last partial symbol being terminated, if necessary, at an end of the respective LDPC codeword). The round-robin looping over spatial streams, however, may continue between LDPC codewords, such that the QAM modulator 640 may begin modulating a next LDPC codeword by generating a QAM symbol 645 for a next spatial steam in the loop.

The modulation scheme 500 and the modulation scheme 600 may support inputs, or LDPC codewords, of any size (e.g., as long as the size is known). However, for both of the modulation scheme 500 and the modulation scheme 600, a QAM modulator 540 or a QAM modulator 640 performing a second phase of modulation may result in increased complexity and decreased performance (e.g., as compared to only performing the first phase of modulation). However, due to a relationship between constellation shaped QAM modulation and LDPC encoding, the second phase of modulation may be avoided when the following condition is met:

$$\frac{R}{1 - R} = \frac{{N}_{Q A M} - 2}{2}$$

In other words, when a first ratio of a first quantity of shaped systematic bits to second quantity parity bits in an LDPC code (e.g., one or more LDPC codewords) is equal to a second ratio of a third quantity of bits used to generate the amplitude of each component (e.g., I component and Q component), which may be referred to as amplitude bits, to a fourth quantity of bits used to generate the sign of each component, which may be referred to as sign bits, then the QAM modulator 640 (e.g., QAM modulator 540) may not have leftover bits in either the parity queue or the systematic queue at a conclusion of modulating all coded bits (e.g., for the modulation scheme 500) or at a conclusion of modulating all coded bits for each LDPC codeword (e.g., for the modulation scheme 600). The following techniques may be described in the context of FIG. 6, however, this is not to be regarded as a limitation of the present disclosure, as the same techniques may be applied in the context of FIG. 5.

Thus, to achieve no leftover bits, a transmitter may be designed such that the LDPC encoder 615 and the QAM modulator 640 work jointly. In other words, the LDPC encoder 615 and the QAM modulator 640 may coordinate processes that are dependent on an MCS associated with the QAM modulator 640, where the MCS defines an encoding rate, ‘R,’ and a QAM modulation order ‘M.’ That is, the LDPC encoder 615, based on the encoding rate and the QAM modulation order, may produce one or more LDPC codewords of a length ‘L,’ and of a composition of one or more shaped systematic bits and one or more parity bits. The QAM modulator 640 may then receive the one or more LDPC codeword and, based on the MCS, select a queue modulation mapping (e.g., which and how many bits from each queue go where in a QAM symbol 645), such that all shaped systematic bits and all parity bits (e.g., in an LDPC codeword for the modulation scheme 500, in the one or more LDPC codewords of the LDPC code for the modulation scheme 600) are used and an integer quantity of complete QAM symbols 645 are generated. Accordingly, the LDPC encoder 615, the QAM modulator 640, or both, may employ one or more methods for altering LDPC codeword composition (e.g., composition of shaped systematic bits and parity bits) to align (e.g., to match) a quantity of shaped systematic bits and parity bits of an LDPC codeword with a ratio associated (e.g., needed by) the QAM modulator 640 to support generation of the integer quantity of complete QAM symbols 645 using all shaped systematic bits and all parity bits.

According to a first method, a transmitter (e.g., the LDPC encoder 615) may alter a first quantity of shaped systematic bits and a second quantity of parity bits (e.g., from nominal starting values for each based on an LDPC codeword size and encoding rate) to match a ratio of a third quantity of bits used to generate the amplitude of each component (e.g., I component and Q component), which may be referred to as amplitude bits, to a fourth quantity of bits used to generate the sign of each component, which may be referred to as sign bits, used by (e.g., needed by) the QAM modulator 640. Altering the quantities of shaped systematic bits and parity bits may change an effective rate of the LDPC encoder 615 from a nominal rate, which may result in an decrease to data rate, performance, or both, however, altering the quantities of shaped systematic bits and parity bits may also allow the QAM modulator 640 to finish modulating LDPC codewords (e.g., LDPC coded bits) in the first phase of modulation without moving to the second phase of modulation, which may reduce complexity and increase performance.

In such cases, the LDPC encoder 615 may alter the LDPC codeword composition (e.g., the first quantity of shaped systematic bits and the second quantity of parity bits in each codeword) depending on different scenarios. In the context of the first method, a nominal LDPC codeword (e.g., what the LDPC encoder 615 produces without shortening, puncturing, or repetition) may be defined according to Table 1.

TABLE 1
Nominal LDPC Codeword, First Method

| Quantity of | | |
|---|---|---|
| Systematic Bits | Shortening | Puncturing |
| N_{sys} = L_{LDPC, nom}R | Nₛₕᵣₜ = 0 | N_{punc} = 0 |
| Quantity of | | |
| Parity Bits | Codeword Size | Encoding Rate |
| Nₚₐᵣ = L_{LDPC, nom}R(1 − R) | L_{CW} = L_{LDPC, nom} | R |

Thus, an altered encoding rate, ‘R_{needed},’ associated with the first quantity of shaped systematic bits and the second quantity of parity bits matching the ratio of the amplitude bits to the sign bits used by the QAM modulator 640 may be determined based on

$$\frac{{R}_{n e e d e d}}{1 - {R}_{n e e d e d}} = \frac{{N}_{Q A M} - 2}{2} .$$

In some cases, R=R_{needed}, such that the LDPC encoder 615 may not make any alterations to the composition of nominal LDPC codewords.

In some other cases, R>R_{needed}, such than an excess of shaped systematic bits to parity bits may exist in each LDPC codeword, such that the LDPC encoder 615 may alter the composition of nominal LDPC codewords (e.g., LDPC codeword composition) in accordance with Table 2, where a total quantity of QAM symbols 645, ‘N_{qs},’ generated by the QAM modulator 640 for each LDPC codeword may be equal to

$$⌊ \frac{{L}_{L DPC , nom} R ( 1 - R )}{2} ⌋ .$$

TABLE 2
Altered LDPC Codeword, R > R_{needed}

| Quantity of | | |
|---|---|---|
| Systematic Bits | Shortening | Puncturing |
| N_{sys} = N_{qs}(N_{QAM} − 2) | Nₛₕᵣₜ = L_{LDPC,nom} | N_{punc} = L_{LDPC,nom} |
| | R − N_{sys} | (1 − R) − 2N_{QS} |
| Quantity of | | |
| Parity Bits | Codeword Size | Encoding Rate |
| Nₚₐᵣ = L_{LDPC,nom} (1 − R) − N_{punc} | L_{CW} = N_{sys} + Nₚₐᵣ | ${R}_{eff} = \frac{{N}_{sys}}{{N}_{sys} + {N}_{par}}$ |

For example, Table 3 depicts an example of altering a LDPC codeword composition generated according to R=5/6 with a nominal size of 1944-bits to match a ratio of a third quantity of bits used to generate the amplitude bits to a fourth quantity of bits used to generate the sign bits used by the QAM modulator 640 for 1024 QAM (e.g., N_{QAM}=10), where a total quantity of QAM symbols 645, ‘N_{qs},’ generated by the QAM modulator 640 for each LDPC codeword is 162 QAM symbols 645 (e.g., to avoid the second phase of modulation).

TABLE 3
$Altered LDPC Codeword , R = \frac{5}{6} < {R}_{needed} = 4 / 5$

| Quantity of Systematic | | |
|---|---|---|
| Bits | Shortening | Puncturing |
| 1296 | 324 | 0 |
| Quantity of | | |
| Parity Bits | Codeword Size | Encoding Rate |
| 324 | 1620 | 4/5 |

In some other cases, R<R_{needed}, such than an excess of parity bits to shaped systematic bits may exist in each LDPC codeword, such that the LDPC encoder 615 may alter the composition of nominal LDPC codewords (e.g., LDPC codeword composition) in accordance with Table 4, where a total quantity of QAM symbols 645, ‘N_{qs},’ generated by the QAM modulator 640 for each LDPC codeword may be equal to

$$⌊ \frac{{L}_{L DPC , nom} R}{2} ⌋ .$$

TABLE 4
Altered LDPC Codeword, R < R_{needed}

| Quantity of | | |
|---|---|---|
| Systematic Bits | Shortening | Puncturing |
| N_{sys} = N_{qs}(N_{QAM} − 2) | Nₛₕᵣₜ = L_{LDPC,nom} | N_{punc} = L_{LDPC,nom} |
| | R − N_{sys} | (1 − R)− Nₚₐᵣ |
| Quantity of | | |
| Parity Bits | Codeword Size | Encoding Rate |
| Nₚₐᵣ = 2N_{QS} | L_{CW} = N_{sys} + Nₚₐᵣ | ${R}_{eff} = \frac{{N}_{sys}}{{N}_{sys} + {N}_{par}}$ |

For example, Table 5 depicts an example of altering an LDPC codeword composition generated according to R=3/4 with a nominal size of 1944-bits to match a ratio of a third quantity of bits used to generate the amplitude bits to a fourth quantity of bits used to generate the sign bits used by the QAM modulator 640 for 1024 QAM (e.g., N_{QAM}=10), where a total quantity of QAM symbols 645, ‘N_{qs},’ generated by the QAM modulator 640 for each LDPC codeword is 182 QAM symbols 645 (e.g., to avoid the second phase of modulation).

TABLE 5
$Altered LDPC Codeword , R = \frac{5}{6} < {R}_{needed} = 4 / 5$

| Quantity of | | |
|---|---|---|
| Systematic Bits | Shortening | Puncturing |
| 1456 | 2 | 122 |
| Quantity of | | |
| Parity Bits | Codeword Size | Encoding Rate |
| 364 | 1820 | 4/5 |

According to a second method, the transmitter (e.g., the LDPC encoder 615) may perform smaller adjustments to the composition of the nominal LDPC codeword (e.g., as compared to the first method) and the QAM modulator 640 may adjust a method of modulating LDPC codewords. Specifically, instead of the first phase of modulation, as described with reference to the modulation scheme 500, the modulation scheme 600, or both, in which shaped systematic bits are used for amplitude bits and parity bits are used for sign bits, the QAM modulator 640 (e.g., from the beginning of modulation) may use parity bits for some of the amplitude bits (e.g., to modulate some parts of the amplitude bits of each component or of each QAM symbol, such as the LSB bits), may use shaped systematic bits for some of the sign bits (e.g., to modulate some parts of the sign of each component), or both. Similar to the first method, the second method may enable the QAM modulator 640 to avoid the second phase of modulation.

In some cases, LDPC codewords may have excess shaped systematic bits for a QAM modulation order, such that some sign bits of certain QAM symbols 645 may be drawn from the systematic queue. Conversely, in some cases, LDPC codewords may have an excess of parity bits, such that some amplitudes bits (e.g., least significant bits (LSBs)) of an I component, a Q component, or both, of some QAM symbols 645 may be drawn from the parity bit queue. In such cases, the shaper 610 may change, such that the shaper 610 may output shaped groups (e.g., bit-tuples) of a smaller size (e.g., as compared to when the second method is not employed). Leaving some amplitude bits of the I component, the Q component, or both, of a QAM symbols 645 unshaped may result in a reduction in constellation shaped power gain (e.g., as compared to when the second method is not employed). However, this reduction may be less than (e.g., compared to) a performance reduction associated with the second phase of modulation in which excess parity bits may be used to modulate fully unshaped QAM symbols 645.

In the context of the first method, a nominal LDPC codeword (e.g., what the LDPC encoder 615 produces without shortening, puncturing, or repetition) may be defined according to Table 6, where a total quantity of QAM symbols 645, ‘N_{qs},’ generated by the QAM modulator 640 for each LDPC codeword may be equal to

$$⌊ \frac{{L}_{L DPC , nom} R ( 1 - R )}{{N}_{Q A M}} ⌋ .$$

TABLE 6
Nominal LDPC Codeword, Second Method

| Quantity of | | |
|---|---|---|
| Systematic Bits | Shortening | Puncturing |
| N_{sys} = RL_{LDPC,nom} − Nₛₕᵣₜ | Nₛₕᵣₜ = L_{LDPC,nom} − L_{CW} | 0 |
| Quantity of | | |
| Parity Bits | Codeword Size | Encoding Rate |
| Nₚₐᵣ = (1 − R)L_{LDPC,nom} | L_{CW} = N_{qs}N_{QAM} | ${R}_{eff} = \frac{{N}_{sys}}{{N}_{sys} + {N}_{par}}$ |

Thus, the transmitter (e.g., LDPC encoder 615) may determine how to alter the LDPC codeword composition in the case of excess parity bits as follows:
1. Define s₁ as a quantity of fully shaped QAM symbols 645 out of the total quantity of QAM symbols 645, ‘N_{qs},’ for each LDPC codeword.
2. Define s₂ as a quantity of partially shaped QAM symbols 645 out of the total quantity of QAM symbols 645, ‘N_{qs},’ for each LDPC codeword, where some amplitude bits (e.g., LSBs) of the partially shaped QAM symbols 645 are using parity bits.
3. Define p_{LSB} as a total number of amplitude bits (e.g., LSBs) over I and Q components of the partially shaped QAM symbols 645 that are using parity bits.
4. Solve for s₁ and s₂ in Equation 5 and Equation 6 (e.g., single-unknown variable equations), respectively, using a predetermined test value for p_{LSB} and using Nₚₐᵣ and N_{sys} values determined according to Table 6.

$$2 {s}_{1} + ( 2 + {p}_{L S B} ) ( {N}_{q s} - {s}_{1} ) = {N}_{p a r} \qquad ( 5 )$$

$$( {N}_{Q A M} - 2 ) {s}_{2} + ( {N}_{Q A M} - 2 - {p}_{L S B} ) ( {N}_{q s} - {s}_{2} ) = {N}_{s y s} \qquad ( 6 )$$

If the resulting s₁ and s₂ values are equal (e.g., the same value) then a valid LDPC codeword composition where the QAM modulator 640 may not have any excess bits (e.g., and hence not perform the second stage of modulation) may be based on a first s₁ QAM symbols 645 formed from the shaped systematic bits and the parity bits of an LDPC codewords being fully shaped and the remaining N_{qs}−s₁ QAM symbols 645 of the LDPC codeword being partially shaped, with p_{LSB} amplitude component bits of each QAM symbol 645 using parity bits.

For example, for 256 QAM in which p_{LSB}=1 and N_{QAM}=8, the QAM modulation may generate a first QAM symbol 645 in which 4 shaped systematic bits may be used for I-Amp of the first QAM symbol 645 and 4 shaped systematic bits may be used for Q-Amp bits of the first QAM symbol 645. Additionally, for an s₁+1 QAM symbol 645, 4 shaped systematic bits may be used for I-Amp of the s₁+1 QAM symbol 645 and 3 shaped systematic bits may be used for Q-Amp bits of the s₁+1 QAM symbol. In another example, for 256 QAM in which p_{LSB}=2 and N_{QAM}=8, the QAM modulation may generate a first QAM symbol 645 in which 4 shaped systematic bits may be used for I-Amp of the first QAM symbol 645 and 4 shaped systematic bits may be used for Q-Amp bits of the first QAM symbol 645. Additionally, for an s₁+1 QAM symbol 645, 3 shaped systematic bits may be used for I-Amp of the s₁+1 QAM symbol 645 and 3 shaped systematic bits may be used for Q-Amp bits of the s₁+1 QAM symbol.

In some cases (e.g., unequal modulation MIMO), LDPC codewords may be constructed such that each LDPC codeword for a given configuration (e.g., unequal QAM modulation configuration, QAM modulation order per stream configuration and LDPC encoding rate) may be of a same size and an integer number of QAM symbols may be produced from each LDPC codeword. Additionally, in some cases (e.g., for unequal modulation MIMO), one LDPC codeword may produce an equal quantity of QAM symbols 645 for a total quantity of spatial streams, ‘Nₛₛ,’ which may result in the QAM modulator 640 starting modulation of each LDPC codeword on a first spatial stream index (e.g., of spatial stream indices associated with the total quantity of spatial streams). Additionally, (e.g., for unequal modulation MIMO), a QAM modulation order for subsequent spatial stream indices may be equal to or less than a QAM modulation order for a previous spatial stream indices.

As described previously, some LDPC codeword parameters (e.g., defining an LDPC codeword composition) may be modified such that an effective encoding rate of an LDPC codeword (e.g., systematic bits to total bits) matched a rate used (e.g., needed) by the QAM modulator 640 to generate an integer quantity (e.g., number) of QAM symbols 645 without leftover bits. However, in some cases (e.g., for unequal modulation MIMO), a target effective rate for one or more LDPC codewords may be defined according to according to the following Equation 7:

$${R}_{eff} = \frac{{\sum }_{i ∈ {N}_{s s}} ( {N}_{Q AM , i} - 2 )}{{\sum }_{i ∈ {N}_{s s}} {N}_{Q AM , i}} \qquad ( 7 )$$

where ‘i’ may represent a spatial stream index, ‘N_{QAM}’ may represent a quantity of bits carrier by a QAM symbol 645 on a spatial stream with spatial stream index ‘i,’ and the summations may be over all ‘Nₛₛ’ spatial streams. In such cases, when constellation shaping is used (e.g., with unequal modulation MIMO), a nominal encoding rate of the LDPC encoder, ‘R,’ may be decoupled from MCS table pairings with QAM modulation orders (e.g., a table of pairings between MCS and QAM modulation order). That is, QAM modulation order per spatial stream and a quantity of spatial streams may be specified in the MCS table, and the LDCP encoding rate, ‘R,’ may be selected as a function of a target effecting LDCP encoding rate, ‘R_{eff}’ In some cases (e.g., option 1), the QAM modulator 645 may select a lowest defined LDPC encoding rate, ‘R,’ (e.g., from the MCS table) that is greater than or equal to ‘R_{eff}.’ In such cases, the LDPC encoding rate, ‘R,’ may be used (e.g., by the QAM modulator 640) to determine a quantity of QAM symbols 645 per spatial stream, ‘N_{qsss},’ according to the following Equation 8:

$${N}_{q s s s} = ⌊ \frac{{L}_{L D P C , n o m} \times ( 1 - R )}{2 \times {N}_{s s}} ⌋ \qquad ( 8 )$$

In some other cases (e.g., option 2), the QAM modulator 640 may select a highest defined LDPC encoding rate, ‘R,’ (e.g., from the MCS table) that is less than or equal to ‘R_{eff}.’ In such cases, the LDPC encoding rate, ‘R,’ may be used (e.g., by the QAM modulator 645) to determine a quantity of QAM symbols 645 per spatial stream according to the following Equation 9:

$${N}_{q s s s} = ⌊ \frac{{L}_{L D PC , nom} \times R}{{\sum }_{i ∈ {N}_{s s}} ( {N}_{Q A M , i} - 2 )} ⌋ \qquad ( 9 )$$

For both cases (e.g., option 1 and option 2), the QAM modulator 645 may determine a quantity of shortening bits ‘Nₛₕᵣₜ,’ based on a quantity of systematic bits used to generate QAM symbols 645 according to the following Equation 10:

$${N}_{s h r t} = ( {L}_{L D P C} \times R ) - {N}_{q s s s} \times {\sum }_{i ∈ {N}_{s s}} ( {N}_{Q A M , i} - 2 ) \qquad ( 10 )$$

Additionally, the QAM modulator 640 may determine a quantity of parity bits, N_{parity},’ based on a quantity of signs (e.g., needed signs) according to the following Equation 11:

$${N}_{p a r i t y} = {N}_{s s} \times {N}_{q s s s} \times 2 \qquad ( 11 )$$

Additionally, the QAM modulator 640 may determine a quantity of bits to puncture, N_{punc},’ according to the following Equation 12:

$${N}_{p u n c} = ( {L}_{L D P C} \times ( 1 - R ) ) - {N}_{p a r i t y} \qquad ( 12 )$$

In summary, in some cases (e.g., option 1), LDPC codeword compositions may be defined according to Table 7, where a total quantity of QAM symbols 645 per spatial stream is

$$⌊ \frac{{L}_{L D P C , n o m} ( 1 - R )}{2 {N}_{s s}} ⌋ ,$$

and, in some other cases (e.g., option 2), may be defined according to Table 8, where a total quantity of QAM symbols 645 per spatial stream is

$$⌊ \frac{{L}_{L D P C , n o m} R}{{\sum }_{i ∈ {N}_{s s}} ( {N}_{QAM , i} - 2 )} ⌋ .$$

TABLE 7
LDPC Codeword Composition, Option 1

| N_{sys} | Nₛₕᵣₜ | N_{Punc} |
|---|---|---|
| ${N}_{qsss} {\sum }_{i ∈ {N}_{ss}} ( {N}_{QAM , i} - 2 )$ | ${L}_{LDPC} R - {N}_{qsss} {\sum }_{i ∈ {N}_{ss}} ( {N}_{QAM , i} - 2 )$ | L_{LDPC}(1 − R) − N_{parity} |
| N_{parity} | Codeword Size (L_{CW}) | R_{eff} |
| 2NₛₛN_{qsss} | N_{sys} + Nₚₐᵣ | $\frac{{N}_{sys}}{{N}_{sys} + {N}_{par}}$ |

TABLE 8
LDPC Codeword Composition, Option 2

| N_{sys} | Nₛₕᵣₜ | N_{Punc} |
|---|---|---|
| ${N}_{qsss} {\sum }_{i ∈ {N}_{ss}} ( {N}_{QAM , i} - 2 )$ | ${L}_{LDPC} R - {N}_{qsss} {\sum }_{i ∈ {N}_{ss}} ( {N}_{QAM , i} - 2 )$ | L_{LDPC}(1 − R) − N_{parity} |
| N_{parity} | Codeword Size (L_{CW}) | R_{eff} |
| 2NₛₛN_{qsss} | N_{sys} + Nₚₐᵣ | $\frac{{N}_{sys}}{{N}_{sys} + {N}_{par}}$ |

Based on a set of QAM patterns (e.g., allowable unequal modulation QAM patterns) for Nₛₛ=2, 3, and 4, and a flexibility of QAM modulation order and LDPC encoding rate, many possible combinations of QAM modulation order and LDPC encoding rate may support LDPC codeword compositions associated with no leftover bits. For example, for Nₛₛ=2, the QAM modulator 640 may use 256 QAM for modulation of a first spatial stream modulation (e.g., N_{qam}=8, 6 amplitude bits+2 sign bits per QAM symbol 645) and may use 64 QAM for modulation of a second spatial steam (e.g., N_{qam}=6, 4 amplitude bits+2 sign bits per QAM symbol 645), where a nominal LDPC codeword size, ‘L_{LDPC,nom},’ is 1944 bits. To generate QAM symbols 645 for one subcarrier, the QAM modulator 640 may use 10 amplitude bits (e.g., 6+4) and 2 sign bits. Thus, the QAM modulator 640 may use an LDPC code (e.g., a set of LDPC codewords) of systematic bits and parity bits with R_{eff}=0.714.

Thus, in some cases (e.g., option 1), an LDPC encoding rate of R=3/4 may be used by the LDPC encoder 615 and an LDPC codeword composition may be defined according to Table 9.

TABLE 9
LDPC Codeword Composition, R = 3/4, Option 1

| | | | | | | Total | Total | |
|---|---|---|---|---|---|---|---|---|
| | | | | | | Quantity | Quantity of | |
| | | | | | Codeword | of QAM | Modulated | |
| Nₛₛ | N_{sys} | Nₛₕᵣₜ | N_{Punc} | N_{Parity} | Size | symbols 645 | Subcarriers | R_{eff} |
| 2 | 1210 | 248 | 2 | 484 | 1694 | 242 | 121 | 0.714 |

In some other cases (e.g., option 2), an LDPC encoding rate of R=2/3 may be used by the LDPC encoder 615 and an LDPC codeword composition may be defined according to Table 10.

TABLE 10
LDPC Codeword Composition, R = 2/3, Option 2

| | | | | | | Total | Total | |
|---|---|---|---|---|---|---|---|---|
| | | | | | | Quantity | Quantity of | |
| | | | | | Codeword | of QAM | Modulated | |
| Nₛₛ | N_{sys} | Nₛₕᵣₜ | N_{Punc} | N_{Parity} | Size | symbols 645 | Subcarriers | R_{eff} |
| 2 | 1290 | 6 | 132 | 516 | 1806 | 258 | 129 | 0.714 |

In some cases, the QAM modulator 640 may support different LDPC codeword compositions that may enable the QAM modulator 640 to complete modulation in the first phase of modulation (e.g., with using the second phase of modulation). That is, in some cases (e.g., 802.11), an MCS table may define valid QAM modulation order and LDPC encoding rate combinations to achieve a range of spectral efficiencies (e.g., data rates). With constellation shaping, similar or the same range of spectral efficiencies may be achieved through different combinations of QAM modulation orders and LDPC encoding rates (e.g., with addition constellation shaping steps applied) with an additional benefit of constellation shaping power gain for improved performance. For example, in some cases, according to a first MCS table, the following LDPC encoding rate (e.g., LDPC rate) and QAM modulation order combinations may be associated with

$$\frac{R}{1 - R} = \frac{{N}_{Q A M} - 2}{2}$$

(e.g., matching ratios between effecting LDPC encoding rate and amplitude and signs bits associated with a QAM modulation order), such that the QAM modulator 640 may complete modulation in the first phase of modulation: MCS=13 with R=5/6 (e.g., with a shaping rate of 0.90 or 0.83), MCS=8 with R=3/4 (e.g., with a shaping rate of 0.89, 0.83, 0.75, or 0.67), and MCS=5 with R=2/3 (e.g., with a shaping rate of 0.83, 0.75, or 0.67). In some cases, for MCS=11 with R=5/6 (e.g., with a shaping rate of 0.94, 0.83, or 0.75) or MCS=10 with R=3/4 (e.g., with a shaping rate of 0.94, 0.83, or 0.75), the LDPC encoder 615 may change an effective LDPC encoding rate from either the nominal LDPC encoding rate of 5/6 or 3/4. The resulting effective LDPC encoding rate may be 4/5 and, using LDPC composition matched codeword definitions, the QAM modulator 640 may be able to modulate LDPC codewords without leftover bits. Additionally, MCS=13 with R=5/6, without shaping, and MCS=3 with R=1/2, without shaping, may not support constellation shaping.

In some other cases, according to a second MCS table, the following LDPC encoding rate (e.g., LDPC rate) and QAM modulation order combinations may be associated with

$$\frac{R}{1 - R} = \frac{{N}_{Q A M} - 2}{2}$$

(e.g., matching ratios between effecting LDPC encoding rate and amplitude and signs bits associated with a QAM modulation order), such that the QAM modulator 640 may complete modulation in the first phase of modulation: MCS=13 with R=5/6 (e.g., with a shaping rate of 0.90), MCS=8 with R=3/4 (e.g., with a shaping rate of 0.89 or 0.83), and MCS=5 with R=2/3 (e.g., with a shaping rate of 0.83, 0.75, or 0.67). Conversely, the following LDPC encoding rate and QAM modulation order combinations may be associated with

$$\frac{R}{1 - R} < \frac{{N}_{Q A M} - 2}{2} ,$$

such that, if given a nominal LDPC codeword of 1944 bits, the QAM modulator 640 may use the second phase of modulation to complete modulation: MCS=12 with R=3/4 (e.g., with a shaping rate of 0.90 or 0.83), MCS=10 with R=3/4 (e.g., with a shaping rate of 0.89 or 0.83), and MCS=7.5 with R=2/3 (e.g., with a shaping rate of 0.84 or 0.75).

Thus, the LDPC codeword composition modification equations (e.g., Equation 5 and Equation 6) may be used to define LDPC codewords of a predetermined size and LDPC codeword composition to be exchanged between the LDPC encoder 615 and the QAM modulator 640, such that the second phased of modulation may be avoided for those MCS when using constellation shaping. A size and LDPC codeword composition of the LDPC codewords may vary by MCS, such that both the LDPC encoder 615 and the QAM modulator 640 may have shared knowledge of the LDPC codeword composition parameters and QAM modulation order being used (e.g., parity least significant bits (p_LSB) and s₁). In some cases, the LDPC codeword composition parameters and QAM modulation order being used may be signaled between the LDPC encoder 615 and the QAM modulator 640 (e.g., and a receiving wireless device). Additionally, or alternatively, the LDPC codeword composition parameters and QAM modulation order being used may MCS dependent, such that a relationship between MCS and both the LDPC codeword composition parameters and QAM modulation order may be preconfigured at the transmitter.

For example, LDPC codewords for 4096 QAM with R=3/4 may be defined according to Table 11.

TABLE 11
Example Codeword Composition, 4096 QAM with R = 3/4

| | | | | | Total |
|---|---|---|---|---|---|
| | | | | | Quantity |
| | | | | | of QAM |
| N_{sys} | Nₛₕᵣₜ | N_{Punc} | N_{Parity} | Codeword Size | symbols 645 |
| 1458 | 0 | 0 | 486 | 1944 | 162 |

In some cases, the LDPC codeword composition parameters may include p_{LSB}=2 and s₁=81, meaning that a first 81 QAM symbols 645 may have 1 parity sign bit and 10 shaped amplitude bits (e.g., 10 amplitude bits based on 10 shaped systematic bits) per QAM symbol 645 and the remaining 81 QAM symbols 645 may have 8 shaped amplitude bits and 2 unshaped amplitude bits (e.g., 8 amplitude bits based on 8 shaped systematic bits and 2 amplitude bits based on 2 parity bits) per QAM symbol 645. That is, the first 81 QAM symbols 645 may include 1 sign parity bit and 5 shaped amplitude bits per I-Amp (e.g., I-PAM), and 1 sign parity bit and 5 shaped amplitude bits per Q-Amp (e.g., Q-PAM). The remaining 81 QAM symbols 645 may include 1 sign parity bit, 4 shaped amplitude bits, and 1 unshaped amplitude bit (e.g., parity bit) per I-Amp (e.g., I-PAM), and 1 sign parity bit, 4 shaped amplitude bits, and 1 unshaped amplitude bit (e.g., parity bit) per Q-Amp.

In some other cases, the LDPC codeword composition parameters may include p_{LSB}=1 and s₁=0, meaning that all 162 QAM symbols will have 9 shaped amplitude bits and 1 unshaped amplitude bit (e.g., 9 amplitude bits based on 9 shaped systematic bits and 1 amplitude bit based on a parity bit) per QAM symbol 645. In some cases, the 1 unshaped amplitude bit may be associated with the I-Amp, such that the 162 QAM symbols 645 may include 4 shaped amplitude bits and 1 unshaped amplitude bit per I-Amp (e.g., I-PAM) and 5 shaped amplitude bits per Q-Amp (e.g., Q-PAM). Each I-Amp may also include 1 sign parity bit, and each Q-Amp may also include 1 sign parity bit. In some other cases, the 1 unshaped amplitude bit may be associated with the I-Amp, such that the 162 QAM symbols 645 may include 5 shaped amplitude bits per I-Amp and 4 shaped amplitude bits and 1 unshaped amplitude bit (e.g., a parity bit) per Q-Amp. Each I-Amp may also include 1 sign parity bit, and each Q-Amp may also include 1 sign parity bit.

In another example, LDPC codewords for 1024 QAM with R=3/4 (e.g., N_{parity}=0.749) may be defined according to Table 12.

TABLE 12
Example Codeword Composition, 1024 QAM with R = 3/4

| | | | | | Total |
|---|---|---|---|---|---|
| | | | | | Quantity |
| | | | | | of QAM |
| N_{sys} | Nₛₕᵣₜ | N_{Punc} | N_{Parity} | Codeword Size | symbols 645 |
| 1454 | 4 | 0 | 486 | 1940 | 194 |

In such cases, the LDPC codeword composition parameters may include p_{LSB}=2 and s₁=145, meaning that a first 145 QAM symbols 645 may have 8 shaped amplitude bits (e.g., 8 amplitude bits based on 8 shaped systematic bits) per QAM symbol 645 and the remaining 49 QAM symbols 645 may have 6 shaped amplitude bits and 2 unshaped amplitude bits (e.g., 6 amplitude bits based on 6 shaped systematic bits and 2 amplitude bits based on 2 parity bits) per QAM symbol 645. That is, the first 145 QAM symbols 645 may include 4 shaped amplitude bits per I-Amp (e.g., I-PAM) and 4 shaped amplitude bits per Q-Amp (e.g., Q-PAM). The first 145 QAM symbols 645 may each also include a 1 sign parity bit per I-Amp and 1 sign parity bit per Q-Amp. The remaining 49 QAM symbols 645 may include 3 shaped amplitude bits and 1 unshaped amplitude bit (e.g., parity bit) per I-Amp and 3 shaped amplitude bits and 1 unshaped amplitude bit (e.g., parity bit) per Q-Amp. The remaining 49 QAM symbols 645 may each also include a 1 sign parity bit per I-Amp and 1 sign parity bit per Q-Amp.

In another example, LDPC codewords for 256 QAM with R=3/4 may be defined according to Table 13.

TABLE 13
Example Codeword Composition, 256 QAM with R = 3/4

| | | | | | Total |
|---|---|---|---|---|---|
| | | | | | Quantity |
| | | | | | of QAM |
| N_{sys} | Nₛₕᵣₜ | N_{Punc} | N_{Parity} | Codeword Size | symbols 645 |
| 296 | 0 | 0 | 648 | 1944 | 243 |

In such cases, the LDPC codeword composition parameters may include p_{LSB}=2 and s₁=162, meaning that a first 162 QAM symbols 645 may have 6 shaped amplitude bits (e.g., 6 amplitude bits based on 6 shaped systematic bits) per QAM symbol 645 and the remaining 81 QAM symbols 645 may have 4 shaped amplitude bits and 2 unshaped amplitude bits (e.g., 4 amplitude bits based on 4 shaped systematic bits and 2 amplitude bits based on 2 parity bits) per QAM symbol 645. That is, the first 145 QAM symbols 645 may include 3 shaped amplitude bits per I-Amp (e.g., I-PAM) and 3 shaped amplitude bits per Q-Amp (e.g., Q-PAM). The first 145 QAM symbols 645 may each also include a 1 sign parity bit per I-Amp and 1 sign parity bit per Q-Amp. The remaining 49 QAM symbols 645 may include 2 shaped amplitude bits and 1 unshaped amplitude bit (e.g., parity bit) per I-Amp and 2 shaped amplitude bits and 1 unshaped amplitude bit (e.g., parity bit) per Q-Amp. The remaining 49 QAM symbols 645 may each also include a 1 sign parity bit per I-Amp and 1 sign parity bit per Q-Amp.

Though depicted in the context of a single spatial stream, this is not to be regarded as a limitation of the present disclosure. In this regard, techniques described herein, specifically with reference to FIG. 6, may be applied to any quantity of spatial streams.

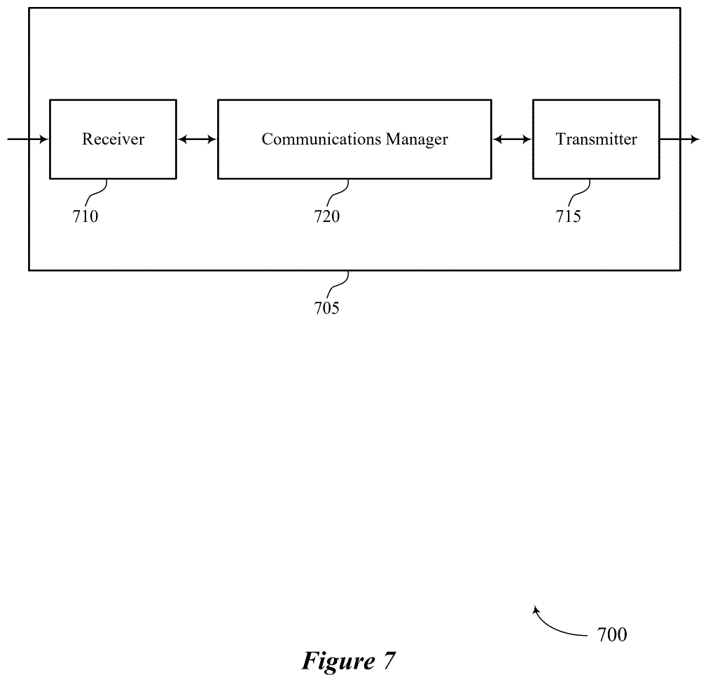

FIG. 7 shows a block diagram 700 of a device 705 that supports techniques for probabilistic constellation shaping in Wi-Fi systems in accordance with one or more aspects of the present disclosure. The device 705 may be an example of aspects of an AP or a STA as described herein. The device 705 may include a receiver 710, a transmitter 715, and a communications manager 720. The device 705, or one or more components of the device 705 (e.g., the receiver 710, the transmitter 715, the communications manager 720), may include at least one processor, which may be coupled with at least one memory, to, individually or collectively, support or enable the described techniques. Each of these components may be in communication with one another (e.g., via one or more buses).

The receiver 710 may provide a means for receiving information such as packets, user data, control information, or any combination thereof associated with various information channels (e.g., control channels, data channels, information channels related to techniques for probabilistic constellation shaping in Wi-Fi systems). Information may be passed on to other components of the device 705. The receiver 710 may utilize a single antenna or a set of multiple antennas.

The transmitter 715 may provide a means for transmitting signals generated by other components of the device 705. The transmitter 715 may utilize a single antenna or a set of multiple antennas.

The communications manager 720, the receiver 710, the transmitter 715, or various combinations or components thereof may be examples of means for performing various aspects of techniques for probabilistic constellation shaping in Wi-Fi systems as described herein. For example, the communications manager 720, the receiver 710, the transmitter 715, or various combinations or components thereof may be capable of performing one or more of the functions described herein.

In some examples, the communications manager 720, the receiver 710, the transmitter 715, or various combinations or components thereof may be implemented in hardware (e.g., in communications management circuitry). The hardware may include at least one of a processor, a DSP, a CPU, an ASIC, an FPGA or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 720, the receiver 710, the transmitter 715, or various combinations or components thereof may be implemented in code (e.g., as communications management software or firmware) executed by at least one processor (e.g., referred to as a processor-executable code). If implemented in code executed by at least one processor, the functions of the communications manager 720, the receiver 710, the transmitter 715, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 720 may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications in accordance with examples as disclosed herein. For example, the communications manager 720 is capable of, configured to, or operable to support a means for receiving a set of multiple information bits for transmission. The communications manager 720 is capable of, configured to, or operable to support a means for applying constellation shaping to the set of multiple information bits to generate a set of multiple shaped information bits. The communications manager 720 is capable of, configured to, or operable to support a means for encoding the set of multiple shaped information bits to generate a stream of parity bits based on an encoding rate and a modulation order associated with generation of a set of multiple modulation symbols, where a stream of systematic bits corresponds to the set of multiple shaped information bits. The communications manager 720 is capable of, configured to, or operable to support a means for transmitting the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

By including or configuring the communications manager 720 in accordance with examples as described herein, the device 705 (e.g., at least one processor controlling or otherwise coupled with the receiver 710, the transmitter 715, the communications manager 720, or a combination thereof) may support techniques for constellation shaping in Wi-Fi systems, which may result in reduced processing, reduced power consumption, and more efficient utilization of communication resources, among other advantages.

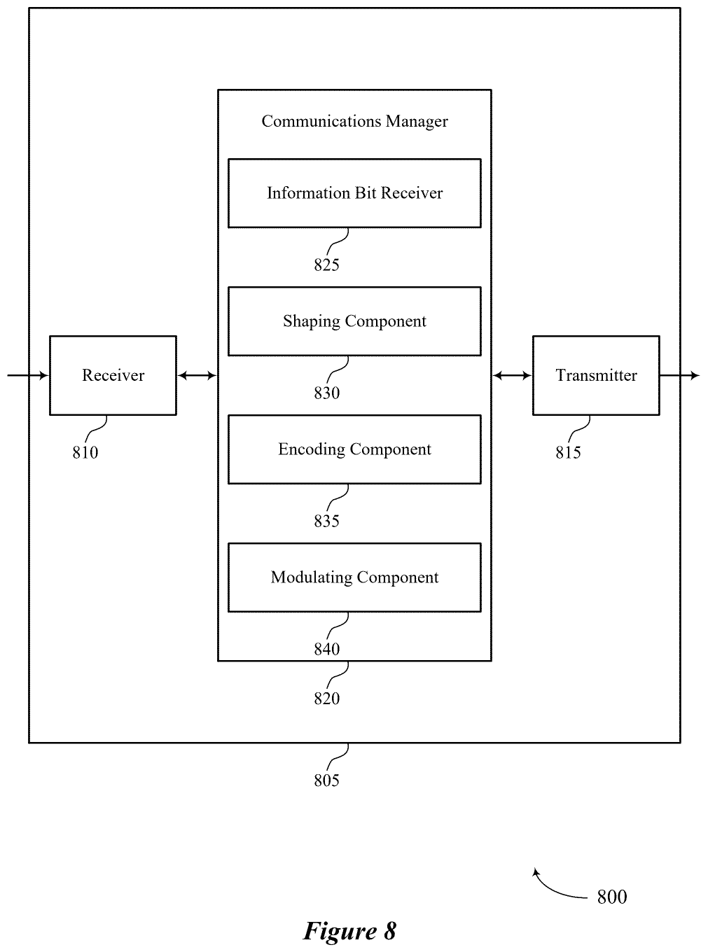

FIG. 8 shows a block diagram 800 of a device 805 that supports techniques for probabilistic constellation shaping in Wi-Fi systems in accordance with one or more aspects of the present disclosure. The device 805 may be an example of aspects of a device 705, an AP 102, or a STA 104 as described herein. The device 805 may include a receiver 810, a transmitter 815, and a communications manager 820. The device 805, or one of more components of the device 805 (e.g., the receiver 810, the transmitter 815, the communications manager 820), may include at least one processor, which may be coupled with at least one memory, to support the described techniques. Each of these components may be in communication with one another (e.g., via one or more buses).

The receiver 810 may provide a means for receiving information such as packets, user data, control information, or any combination thereof associated with various information channels (e.g., control channels, data channels, information channels related to techniques for probabilistic constellation shaping in Wi-Fi systems). Information may be passed on to other components of the device 805. The receiver 810 may utilize a single antenna or a set of multiple antennas.

The transmitter 815 may provide a means for transmitting signals generated by other components of the device 805. The transmitter 815 may utilize a single antenna or a set of multiple antennas.

The device 805, or various components thereof, may be an example of means for performing various aspects of techniques for probabilistic constellation shaping in Wi-Fi systems as described herein. For example, the communications manager 820 may include an information bit receiver 825, a shaping component 830, an encoding component 835, a modulating component 840, or any combination thereof. The communications manager 820 may be an example of aspects of a communications manager 720 as described herein. In some examples, the communications manager 820, or various components thereof, may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communications in accordance with examples as disclosed herein. The information bit receiver 825 is capable of, configured to, or operable to support a means for receiving a set of multiple information bits for transmission. The shaping component 830 is capable of, configured to, or operable to support a means for applying constellation shaping to the set of multiple information bits to generate a set of multiple shaped information bits. The encoding component 835 is capable of, configured to, or operable to support a means for encoding the set of multiple shaped information bits to generate a stream of parity bits based on an encoding rate and a modulation order associated with generation of a set of multiple modulation symbols, where a stream of systematic bits corresponds to the set of multiple shaped information bits. The modulating component 840 is capable of, configured to, or operable to support a means for transmitting the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

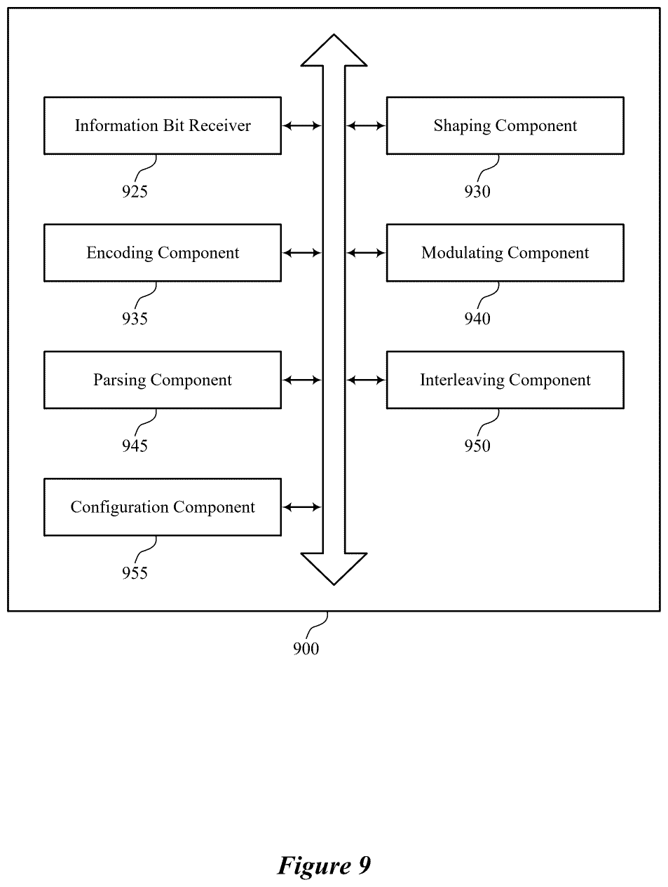

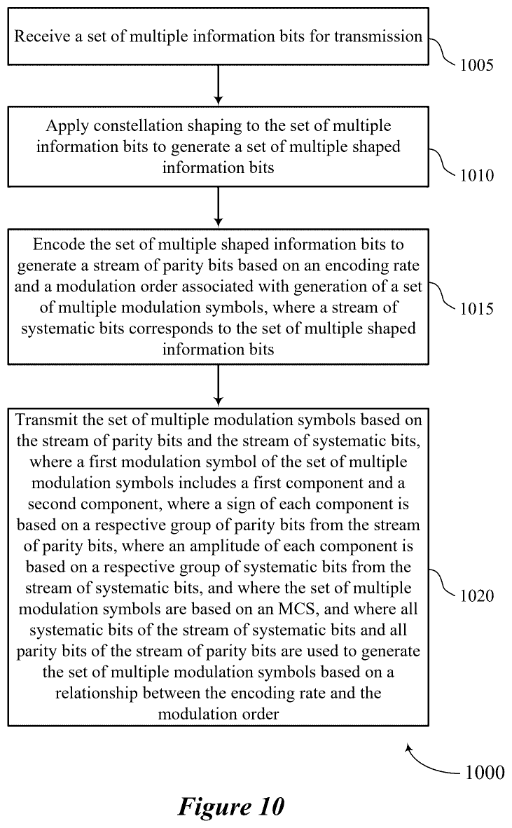

FIG. 9 shows a block diagram of an example wireless communication device 900 that supports techniques for probabilistic constellation shaping in Wi-Fi systems. In some examples, the wireless communication device 900 is configured to perform the process 1000 described with reference to FIG. 10. The wireless communication device 900 may include one or more chips, SoCs, chipsets, packages, components or devices that individually or collectively constitute or include a processing system. The processing system may interface with other components of the wireless communication device 900, and may generally process information (such as inputs or signals) received from such other components and output information (such as outputs or signals) to such other components. In some aspects, an example chip may include a processing system, a first interface to output or transmit information and a second interface to receive or obtain information. For example, the first interface may refer to an interface between the processing system of the chip and a transmission component, such that the wireless communication device 900 may transmit the information output from the chip. In such an example, the second interface may refer to an interface between the processing system of the chip and a reception component, such that the wireless communication device 900 may receive information that is then passed to the processing system. In some such examples, the first interface also may obtain information, such as from the transmission component, and the second interface also may output information, such as to the reception component.

The processing system of the wireless communication device 900 includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor” or “the processor circuitry”). One or more of the processors may be individually or collectively configurable or configured to perform various functions or operations described herein. The processing system may further include memory circuitry in the form of one or more memory devices, memory blocks, memory elements or other discrete gate or transistor logic or circuitry, each of which may include tangible storage media such as random-access memory (RAM) or ROM, or combinations thereof (all of which may be generally referred to herein individually as “memories” or collectively as “the memory” or “the memory circuitry”). One or more of the memories may be coupled with one or more of the processors and may individually or collectively store processor-executable code that, when executed by one or more of the processors, may configure one or more of the processors to perform various functions or operations described herein. Additionally, or alternatively, in some examples, one or more of the processors may be preconfigured to perform various functions or operations described herein without requiring configuration by software. The processing system may further include or be coupled with one or more modems (such as a Wi-Fi (for example, IEEE compliant) modem or a cellular (for example, 3GPP 4G LTE, 5G or 6G compliant) modem). In some implementations, one or more processors of the processing system include or implement one or more of the modems. The processing system may further include or be coupled with multiple radios (collectively “the radio”), multiple RF chains or multiple transceivers, each of which may in turn be coupled with one or more of multiple antennas. In some implementations, one or more processors of the processing system include or implement one or more of the radios, RF chains or transceivers.

In some examples, the wireless communication device 900 can be configurable or configured for use in a communications manager, such as the AP 102 or the STA 104 described with reference to FIG. 1. In some other examples, the wireless communication device 900 can be a communications manager that includes such a processing system and other components including multiple antennas. The wireless communication device 900 is capable of transmitting and receiving wireless communications in the form of, for example, wireless packets. For example, the wireless communication device 900 can be configurable or configured to transmit and receive packets in the form of physical layer PPDUs and MPDUs conforming to one or more of the IEEE 802.11 family of wireless communication protocol standards. In some other examples, the wireless communication device 900 can be configurable or configured to transmit and receive signals and communications conforming to one or more 3GPP specifications including those for 5G NR or 6G. In some examples, the wireless communication device 900 also includes or can be coupled with one or more application processors which may be further coupled with one or more other memories. In some examples, the wireless communication device 900 further includes a user interface (UI) (such as a touchscreen or keypad) and a display, which may be integrated with the UI to form a touchscreen display that is coupled with the processing system. In some examples, the wireless communication device 900 may further include one or more sensors such as, for example, one or more inertial sensors, accelerometers, temperature sensors, pressure sensors, or altitude sensors, that are coupled with the processing system. In some examples, the wireless communication device 900 further includes at least one external network interface coupled with the processing system that enables communication with a core network or backhaul network that enables the wireless communication device 900 to gain access to external networks including the Internet.

The wireless communication device 900 includes an information bit receiver 925, a shaping component 930, an encoding component 935, a modulating component 940, a parsing component 945, an interleaving component 950, and a configuration component 955. Portions of one or more of the information bit receiver 925, the shaping component 930, the encoding component 935, the modulating component 940, the parsing component 945, the interleaving component 950, and the configuration component 955 may be implemented at least in part in hardware or firmware. For example, one or more of the information bit receiver 925, the shaping component 930, the encoding component 935, the modulating component 940, the parsing component 945, the interleaving component 950, and the configuration component 955 may be implemented at least in part by at least a processor or a modem. In some examples, portions of one or more of the information bit receiver 925, the shaping component 930, the encoding component 935, the modulating component 940, the parsing component 945, the interleaving component 950, and the configuration component 955 may be implemented at least in part by a processor and software in the form of processor-executable code stored in memory.

The wireless communication device 900 may support wireless communications in accordance with examples as disclosed herein. The information bit receiver 925 is configurable or configured to receive a set of multiple information bits for transmission. The shaping component 930 is configurable or configured to apply constellation shaping to the set of multiple information bits to generate a set of multiple shaped information bits. The encoding component 935 is configurable or configured to encode the set of multiple shaped information bits to generate a stream of parity bits based on an encoding rate and a modulation order associated with generation of a set of multiple modulation symbols, where a stream of systematic bits corresponds to the set of multiple shaped information bits. The modulating component 940 is configurable or configured to transmit the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order.

In some examples, the encoding rate may be based on an encoding composition, and the encoding composition may be based on a first quantity of parity bits from the stream of parity bits per codeword generated based on the encoding and based at least in part on a second quantity of systematic bits from the stream of systematic bits per codeword generated based on the encoding.

In some examples, the configuration component 955 may communicate a control message indicating the modulation order, the encoding composition, or both, wherein the set of multiple modulation symbols is based on the modulation order, the encoding composition, or both.

In some examples, the modulation order, the encoding composition, or both, may be pre-configured at the first wireless device, and the modulation order, the encoding composition, or both, may be based on the MCS.

In some examples, the stream of parity bits may include a set of multiple parity bit segments, and the stream of systematic bits may include a set of multiple systematic bit segments, and each codeword may include a parity bit segment of the set of multiple parity bit segments and a systematic bit segment of the set of multiple systematic bit segments. In such cases, the configuration component 955 may adjust the first quantity of parity bits in each codeword and the second quantity of systematic bits in each codeword on adjusting the encoding composition, where a ratio between the adjusted first quantity of parity bits and the adjusted second quantity of systematic bits matches a ratio between a third quantity of bits used to generate the sign of each component and a fourth quantity of bits used to generate the amplitude of each component.

In some examples, a first sign of the first component is based on a first group of parity bits of the stream of parity bits. In some examples, a first amplitude of the first component is based on a first group of systematic bits of the stream of systematic bits. In some examples, a second sign of the second component is based on a second group of parity bits of the stream of parity bit. In some examples, a second amplitude of the second component is based on a second group of systematic bits of the stream of systematic bits.

In some examples, the first group of parity bits and the second group of parity bits includes a same quantity of parity bits. In some examples, the first group of systematic bits and the second group of systematic bits includes the same quantity of systematic bits.

In some examples, the first group of parity bits and the second group of parity bits includes a different quantity of parity bits, or the first group of systematic bits and the second group of systematic bits includes a different quantity of systematic bits, or both.

In some examples, a first sign of the first component is based on a first group of parity bits of the stream of parity bits. In some examples, a first amplitude of the first component is based on a first group of systematic bits of the stream of systematic bits and a third group of parity bits from the stream of parity bits. In some examples, a second sign of the second component is based on a second group of parity bits of the stream of parity bit. In some examples, a second amplitude of the second component is based on a second group of systematic bits of the stream of systematic bits and a fourth group of parity bits from the stream of parity bits.

In some examples, the modulating component 940 is configurable or configured to generate a second modulation symbol of the set of multiple modulation symbols that includes a third component and a fourth component, where a sign of each component in the second modulation symbol is based on a respective second group of parity bits from the stream of parity bits, and where an amplitude of each component in the second modulation symbol is based on a respective second group of systematic bits from the stream of systematic bits.

In some examples, a first quantity of parity bits in each group of parity bits is the same as a second quantity of parity bits in each second group of parity bits. In some examples, a first quantity of systematic bits in each group of systematic bits is the same as a second quantity of systematic bits in each second group of systematic bits.

In some examples, a first quantity of parity bits in each group of parity bits is different than as a second quantity of parity bits in each second group of parity bits. In some examples, a first quantity of systematic bits in each group of systematic bits is different than a second quantity of systematic bits in each second group of systematic bits.

In some examples, the stream of parity bits includes a set of multiple parity bit segments. In some examples, the stream of systematic bits includes a set of multiple systematic bit segments. In some examples, both of the first modulation symbol and the second modulation symbol are associated with a first codeword including a first parity bit segment of the set of multiple parity bit segments and a first systematic bit segment of the set of multiple systematic bit segments.

In some examples, the modulating component 940 is configurable or configured to generate a second modulation symbol of the set of multiple modulation symbols that includes a third component and a fourth component, where a sign of each component in the second modulation symbol is based on a respective second group of parity bits from the stream of parity bits, and where an amplitude of each component in the second modulation symbol is based on a respective second group of systematic bits from the stream of systematic bits and a respective third group of parity bits from the stream of parity bits.

In some examples, the stream of parity bits includes a set of multiple parity bit segments, and the modulating component 940 is configurable or configured to generate a first set of modulation symbols of the set of multiple modulation symbols based on a first codeword including a first parity bit segment of the set of multiple parity bit segments and a first systematic bit segment of the set of multiple systematic bit segments. In some examples, the stream of parity bits includes a set of multiple parity bit segments, and the modulating component 940 is configurable or configured to generate a second set of modulation symbols of the set of multiple modulation symbols based on a second codeword including a second parity bit segment of the set of multiple parity bit segments and a second systematic bit segment of the set of multiple systematic bit segments.

In some examples, the parsing component 945 is configurable or configured to parse the set of multiple modulation symbols into a set of multiple streams of modulation symbols, where transmitting the set of multiple modulation symbols comprises transmitting the set of multiple streams of modulation symbols.

In some examples, the parsing component 945 is configurable or configured to parse the stream of parity bits into a set of multiple streams of parity bits. In some examples, the parsing component 945 is configurable or configured to parse the stream of systematic bits into a set of multiple streams of systematic bits. In some examples, the modulating component 940 is configurable or configured to generate, via a respective modulator, a respective subset of the set of multiple modulation symbols based on a respective stream of parity bits and a respective stream of systematic bits, where transmitting the set of multiple modulation symbols comprises transmitting the respective subsets of the set of multiple modulation symbols.

In some examples, the parsing component 945 is configurable or configured to parse the set of multiple information bits between a set of multiple shapers, where each shaper of the set of multiple shapers is associated with a different modulation order. In some examples, to apply the constellation shaping to the set of multiple information bits, the shaping component 930 is configurable or configured to apply, via each shaper of the set of multiple shapers, the constellation shaping to a respective set of information bits from the set of multiple information bits to generate a respective stream of shaped information bits. In some examples, the interleaving component 950 is configurable or configured to interleave the respective streams of information bits to generate a set of multiple interleaved, shaped information bits, where encoding the set of multiple shaped information bits includes encoding the set of multiple interleaved, shaped information bits.

In some examples, a respective ratio of bits incrementally fed to each shaper of the set of multiple shapers relative to a total quantity of bits fed to the set of multiple shapers is fixed.

In some examples, a respective first quantity of information bits incrementally fed to each shaper of the set of multiple shapers varies per shaper. In some examples, a second quantity of bits output by each shaper is the same.

In some examples, the first component is an in-phase component of the first modulation symbol, and wherein the second component is a quadrature component of the first modulation symbol.

FIG. 10 shows a flowchart illustrating an example process 1000 performable by or at a first wireless device that supports techniques for probabilistic constellation shaping in Wi-Fi systems. The operations of the process 1000 may be implemented by a first wireless device or its components as described herein. For example, the process 1000 may be performed by a wireless communication device, such as the wireless communication device 900 described with reference to FIG. 9, operating as or within a wireless AP or a wireless STA. In some examples, the process 1000 may be performed by a wireless AP or a wireless STA, such as one of the APs 102 or the STAs 104 described with reference to FIG. 1.

In some examples, in 1005, the first wireless device may receive a set of multiple information bits for transmission. The operations of 1005 may be performed in accordance with examples as disclosed herein. In some implementations, aspects of the operations of 1005 may be performed by an information bit receiver 925 as described with reference to FIG. 9.

In some examples, in 1010, the first wireless device may apply constellation shaping to the set of multiple information bits to generate a set of multiple shaped information bits. The operations of 1010 may be performed in accordance with examples as disclosed herein. In some implementations, aspects of the operations of 1010 may be performed by a shaping component 930 as described with reference to FIG. 9.

In some examples, in 1015, the first wireless device may encode the set of multiple shaped information bits to generate a stream of parity bits based on an encoding rate and a modulation order associated with generation of a set of multiple modulation symbols, where a stream of systematic bits corresponds to the set of multiple shaped information bits. The operations of 1015 may be performed in accordance with examples as disclosed herein. In some implementations, aspects of the operations of 1015 may be performed by an encoding component 935 as described with reference to FIG. 9.

In some examples, in 1020, the first wireless device may transmit the set of multiple modulation symbols based on the stream of parity bits and the stream of systematic bits, where a first modulation symbol of the set of multiple modulation symbols includes a first component and a second component, where a sign of each component is based on a respective group of parity bits from the stream of parity bits, where an amplitude of each component is based on a respective group of systematic bits from the stream of systematic bits, and where the set of multiple modulation symbols are based on an MCS, and where all systematic bits of the stream of systematic bits and all parity bits of the stream of parity bits are used to generate the set of multiple modulation symbols based on a relationship between the encoding rate and the modulation order. The operations of 1020 may be performed in accordance with examples as disclosed herein. In some implementations, aspects of the operations of 1020 may be performed by a modulating component 940 as described with reference to FIG. 9.

Implementation examples are described in the following numbered clauses:

The following provides an overview of aspects of the present disclosure:
Aspect 1: A method for wireless communications at a first wireless device, including: receiving a plurality of information bits for transmission; applying constellation shaping to the plurality of information bits to generate a plurality of shaped information bits; encoding the plurality of shaped information bits to generate a stream of parity bits based on an encoding rate and a modulation order associated with generation of a set of multiple modulation symbols, where a stream of systematic bits corresponds to the plurality of shaped information bits; and transmitting the plurality of modulation symbols based at least in part on the stream of parity bits and the stream of systematic bits, where a first modulation symbol of the plurality of modulation symbols includes a first component and a second component, where a sign of each component is based at least in part on a respective group of parity bits from the stream of parity bits, where an amplitude of each component is based at least in part on a respective group of systematic bits from the stream of systematic bits, where the plurality of modulation symbols are based at least in part on an MCS, and where all systematic bits of the stream of systematic bits and all parity bits of the stream of parity bits are used to generate the plurality of modulation symbols based at least in part on a relationship between the encoding rate and the modulation order.
Aspect 2: The method of aspect 1, where the encoding rate is based at least in part on an encoding composition, and where the encoding composition is based at least in part on a first quantity of parity bits from the stream of parity bits per codeword generated based on the encoding and based at least in part on a second quantity of systematic bits from the stream of systematic bits per codeword generated based on the encoding.
Aspect 3: The method of aspect 2, further including: communicating a control message indicating the modulation order, the encoding composition, or both, wherein the plurality of modulation symbols is based at least in part on the modulation order, the encoding composition, or both.
Aspect 4: The method of any of aspects 2-3, where the modulation order, the encoding composition, or both, are pre-configured at the first wireless device, and where the modulation order, the encoding composition, or both, are based at least in part on the modulation and coding scheme.
Aspect 5: The method of any of aspects 2-4, where the stream of parity bits comprises a plurality of parity bit segments, and where the stream of systematic bits comprises a plurality of systematic bit segments, and where each codeword comprises a parity bit segment of the plurality of parity bit segments and a systematic bit segment of the plurality of systematic bit segments, the method further comprising: adjusting the first quantity of parity bits in each codeword and the second quantity of systematic bits in each codeword based at least in part on adjusting the encoding composition, wherein a ratio between the adjusted first quantity of parity bits and the adjusted second quantity of systematic bits matches a ratio between a third quantity of bits used to generate the sign of each component and a fourth quantity of bits used to generate the amplitude of each component
Aspect 6: The method of any of aspects 1-5, where a first sign of the first component is based at least in part on a first group of parity bits of the stream of parity bits, a first amplitude of the first component is based at least in part on a first group of systematic bits of the stream of systematic bits, a second sign of the second component is based on a second group of parity bits of the stream of parity bit, and a second amplitude of the second component is based at least in part on a second group of systematic bits of the stream of systematic bits.
Aspect 7: The method of aspect 6, where the first group of parity bits and the second group of parity bits includes a same quantity of parity bits, and the first group of systematic bits and the second group of systematic bits includes the same quantity of systematic bits.
Aspect 8: The method of any of aspects 6-7, where the first group of parity bits and the second group of parity bits includes a different quantity of parity bits, or the first group of systematic bits and the second group of systematic bits includes a different quantity of systematic bits, or both.
Aspect 9: The method of any of aspects 1-8, where a first sign of the first component is based at least in part on a first group of parity bits of the stream of parity bits, a first amplitude of the first component is based at least in part on a first group of systematic bits of the stream of systematic bits and a third group of parity bits from the stream of parity bits, a second sign of the second component is based on a second group of parity bits of the stream of parity bit, and a second amplitude of the second component is based at least in part on a second group of systematic bits of the stream of systematic bits and a fourth group of parity bits from the stream of parity bits.
Aspect 10: The method of any of aspects 1-9, further including: generating a second modulation symbol of the plurality of modulation symbols that includes a third component and a fourth component, where a sign of each component in the second modulation symbol is based at least in part on a respective second group of parity bits from the stream of parity bits, and where an amplitude of each component in the second modulation symbol is based at least in part on a respective second group of systematic bits from the stream of systematic bits.
Aspect 11: The method of aspect 10, where a first quantity of parity bits in each group of parity bits is the same as a second quantity of parity bits in each second group of parity bits, and a first quantity of systematic bits in each group of systematic bits is the same as a second quantity of systematic bits in each second group of systematic bits.
Aspect 12: The method of any of aspects 10-11, where a first quantity of parity bits in each group of parity bits is different than as a second quantity of parity bits in each second group of parity bits, and a first quantity of systematic bits in each group of systematic bits is different than a second quantity of systematic bits in each second group of systematic bits.
Aspect 13: The method of any of aspects 10-12, where the stream of parity bits includes a plurality of parity bit segments, the stream of systematic bits includes a plurality of systematic bit segments, and both of the first modulation symbol and the second modulation symbol are associated with a first codeword including a first parity bit segment of the plurality of parity bit segments and a first systematic bit segment of the plurality of systematic bit segments.
Aspect 14: The method of any of aspects 1-13, further including: generating a second modulation symbol of the plurality of modulation symbols that includes a third component and a fourth component, where a sign of each component in the second modulation symbol is based at least in part on a respective second group of parity bits from the stream of parity bits, and where an amplitude of each component in the second modulation symbol is based at least in part on a respective second group of systematic bits from the stream of systematic bits and a respective third group of parity bits from the stream of parity bits.
Aspect 15: The method of any of aspects 1-14, where the stream of parity bits includes a plurality of parity bit segments, where the stream of systematic bits includes a plurality of systematic bit segments, the method further including: generating a first set of modulation symbols of the plurality of modulation symbols based at least in part on a first codeword including a first parity bit segment of the plurality of parity bit segments and a first systematic bit segment of the plurality of systematic bit segments; and generating a second set of modulation symbols of the plurality of modulation symbols based at least in part on a second codeword including a second parity bit segment of the plurality of parity bit segments and a second systematic bit segment of the plurality of systematic bit segments.
Aspect 16: The method of any of aspects 1-15, further including: parsing the plurality of modulation symbols into a plurality of streams of modulation symbols, wherein transmitting the plurality of modulation symbols includes transmitting the plurality of streams of modulation symbols.
Aspect 17: The method of any of aspects 1-16, further including: parsing the stream of parity bits into a plurality of streams of parity bits; parsing the stream of systematic bits into a plurality of streams of systematic bits; and generating, via a respective modulator, a respective subset of the plurality of modulation symbols based at least in part on a respective stream of parity bits and a respective stream of systematic bits, wherein transmitting the plurality of modulation symbols includes transmitting the respective subsets of the plurality of modulation symbols.
Aspect 18: The method of any of aspects 1-17, further including: parsing the plurality of information bits between a plurality of shapers, where each shaper of the plurality of shapers is associated with a different modulation order, and where applying the constellation shaping to the plurality of information bits includes: applying, via each shaper of the plurality of shapers, the constellation shaping to a respective set of information bits from the plurality of information bits to generate a respective stream of shaped information bits; and interleaving the respective streams of information bits to generate a plurality of interleaved, shaped information bits, wherein encoding the plurality of shaped information bits includes encoding the plurality of interleaved, shaped information bits.
Aspect 19: The method of aspect 18, where a respective ratio of bits incrementally fed to each shaper of the plurality of shapers relative to a total quantity of bits fed to the plurality of shapers is fixed.
Aspect 20: The method of any of aspects 18-19, where a respective first quantity of information bits incrementally fed to each shaper of the plurality of shapers varies per shaper, and a second quantity of bits output by each shaper is the same.
Aspect 21: The method of any of aspects 1-20, where the first component is an in-phase component of the first modulation symbol, and the second component is a quadrature component of the first modulation symbol.
Aspect 22: A first wireless device for wireless communications, including one or more memories storing processor-executable code, and one or more processors coupled with the one or more memories and individually or collectively operable to execute the code to cause the first wireless device to perform a method of any of aspects 1-21.
Aspect 23: A first wireless device for wireless communications, including at least one means for performing a method of any of aspects 1-21.
Aspect 24: A non-transitory computer-readable medium storing code for wireless communications, the code including instructions executable by one or more processors to perform a method of any of aspects 1-21.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Furthermore, as used herein, a phrase referring to “a” or “an” element refers to one or more of such elements acting individually or collectively to perform the recited function(s). Additionally, a “set” refers to one or more items, and a “subset” refers to less than a whole set, but non-empty.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.”

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

Various modifications to the examples described in this disclosure may be readily apparent to persons having ordinary skill in the art, and the generic principles defined herein may be applied to other examples without departing from the scope of this disclosure. Thus, the claims are not intended to be limited to the examples shown herein, but are to be accorded the widest scope consistent with this disclosure, the principles and the novel features disclosed herein.

Additionally, various features that are described in this specification in the context of separate examples also can be implemented in combination in a single implementation. Conversely, various features that are described in the context of a single implementation also can be implemented in multiple examples separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together in a single software product or packaged into multiple software products.

What is claimed is:

1. A first wireless device, comprising:
a processing system that includes processor circuitry and memory circuitry that stores code, the processing system configured to cause the first wireless device to:
receive a plurality of information bits for transmission;
apply constellation shaping to the plurality of information bits to generate a plurality of shaped information bits;
encode the plurality of shaped information bits to generate a stream of parity bits based at least in part on an encoding rate and a modulation order associated with generation of a plurality of modulation symbols, wherein a stream of systematic bits corresponds to the plurality of shaped information bits; and
transmit the plurality of modulation symbols based at least in part on the stream of parity bits and the stream of systematic bits, wherein a first modulation symbol of the plurality of modulation symbols comprises a first component and a second component, wherein a sign of each component is based at least in part on a respective group of parity bits from the stream of parity bits, wherein an amplitude of each component is based at least in part on a respective group of systematic bits from the stream of systematic bits, wherein the plurality of modulation symbols are based at least in part on a modulation and coding scheme (MCS), and wherein all systematic bits of the stream of systematic bits and all parity bits of the stream of parity bits are used to generate the plurality of modulation symbols based at least in part on a relationship between the encoding rate and the modulation order.

2. The first wireless device of claim 1, wherein the encoding rate is based at least in part on an encoding composition, and wherein the encoding composition is based at least in part on a first quantity of parity bits from the stream of parity bits per codeword generated based at least in part on the encoding and based at least in part on a second quantity of systematic bits from the stream of systematic bits per codeword generated based at least in part on the encoding.

3. The first wireless device of claim 2, wherein the processing system is further configured to cause the first wireless device to:
communicate a control message indicating the modulation order, the encoding composition, or both, wherein the plurality of modulation symbols is based at least in part on the modulation order, the encoding composition, or both.

4. The first wireless device of claim 2, wherein:
the modulation order, the encoding composition, or both, are pre-configured at the first wireless device, and
the modulation order, the encoding composition, or both, are based at least in part on the modulation and coding scheme.

5. The first wireless device of claim 2, wherein the stream of parity bits comprises a plurality of parity bit segments, and wherein the stream of systematic bits comprises a plurality of systematic bit segments, and wherein each codeword comprises a parity bit segment of the plurality of parity bit segments and a systematic bit segment of the plurality of systematic bit segments, and wherein the processing system is further configured to cause the first wireless device to:
adjust the first quantity of parity bits in each codeword and the second quantity of systematic bits in each codeword based at least in part on adjusting the encoding composition, wherein a ratio between the adjusted first quantity of parity bits and the adjusted second quantity of systematic bits matches a ratio between a third quantity of bits used to generate the sign of each component and a fourth quantity of bits used to generate the amplitude of each component.

6. The first wireless device of claim 1, wherein a first sign of the first component is based at least in part on a first group of parity bits of the stream of parity bits, wherein a first amplitude of the first component is based at least in part on a first group of systematic bits of the stream of systematic bits, wherein a second sign of the second component is based at least in part on a second group of parity bits of the stream of parity bit, and wherein a second amplitude of the second component is based at least in part on a second group of systematic bits of the stream of systematic bits.

7. The first wireless device of claim 6, wherein the first group of parity bits and the second group of parity bits comprises a same quantity of parity bits, and wherein the first group of systematic bits and the second group of systematic bits comprises the same quantity of systematic bits.

8. The first wireless device of claim 6, wherein the first group of parity bits and the second group of parity bits comprises a different quantity of parity bits, or the first group of systematic bits and the second group of systematic bits comprises a different quantity of systematic bits, or both.

9. The first wireless device of claim 1, wherein a first sign of the first component is based at least in part on a first group of parity bits of the stream of parity bits, wherein a first amplitude of the first component is based at least in part on a first group of systematic bits of the stream of systematic bits and a third group of parity bits from the stream of parity bits, wherein a second sign of the second component is based at least in part on a second group of parity bits of the stream of parity bit, and wherein a second amplitude of the second component is based at least in part on a second group of systematic bits of the stream of systematic bits and a fourth group of parity bits from the stream of parity bits.

10. The first wireless device of claim 1, wherein the processing system is further configured to cause the first wireless device to:
generate a second modulation symbol of the plurality of modulation symbols that comprises a third component and a fourth component, wherein a sign of each component in the second modulation symbol is based at least in part on a respective second group of parity bits from the stream of parity bits, and wherein an amplitude of each component in the second modulation symbol is based at least in part on a respective second group of systematic bits from the stream of systematic bits.

11. The first wireless device of claim 10, wherein a first quantity of parity bits in each group of parity bits is the same as a second quantity of parity bits in each second group of parity bits, and wherein a first quantity of systematic bits in each group of systematic bits is the same as a second quantity of systematic bits in each second group of systematic bits.

12. The first wireless device of claim 10, wherein a first quantity of parity bits in each group of parity bits is different than a second quantity of parity bits in each second group of parity bits, and wherein a first quantity of systematic bits in each group of systematic bits is different than a second quantity of systematic bits in each second group of systematic bits.

13. The first wireless device of claim 10, wherein the stream of parity bits comprises a plurality of parity bit segments, wherein the stream of systematic bits comprises a plurality of systematic bit segments, and wherein both of the first modulation symbol and the second modulation symbol are associated with a first codeword comprising a first parity bit segment of the plurality of parity bit segments and a first systematic bit segment of the plurality of systematic bit segments.

14. The first wireless device of claim 1, wherein the processing system is further configured to cause the first wireless device to:
generate a second modulation symbol of the plurality of modulation symbols that comprises a third component and a fourth component, wherein a sign of each component in the second modulation symbol is based at least in part on a respective second group of parity bits from the stream of parity bits, and wherein an amplitude of each component in the second modulation symbol is based at least in part on a respective second group of systematic bits from the stream of systematic bits and a respective third group of parity bits from the stream of parity bits.

15. The first wireless device of claim 1, wherein the stream of parity bits comprises a plurality of parity bit segments, and the stream of systematic bits comprises a plurality of systematic bit segments, the processing system is further configured to cause the first wireless device to:
generate a first set of modulation symbols of the plurality of modulation symbols based at least in part on a first codeword comprising a first parity bit segment of the plurality of parity bit segments and a first systematic bit segment of the plurality of systematic bit segments; and
generate a second set of modulation symbols of the plurality of modulation symbols based at least in part on a second codeword comprising a second parity bit segment of the plurality of parity bit segments and a second systematic bit segment of the plurality of systematic bit segments.

16. The first wireless device of claim 1, wherein the processing system is further configured to cause the first wireless device to:
parse the plurality of modulation symbols into a plurality of streams of modulation symbols, wherein transmission of the plurality of modulation symbols comprises transmission of the plurality of streams of modulation symbols.

17. The first wireless device of claim 1, wherein the processing system is further configured to cause the first wireless device to:
parse the stream of parity bits into a plurality of streams of parity bits;
parse the stream of systematic bits into a plurality of streams of systematic bits; and
generate, via a respective modulator, a respective subset of the plurality of modulation symbols based at least in part on a respective stream of parity bits and a respective stream of systematic bits, wherein transmission of the plurality of modulation symbols comprises transmission of the respective subsets of the plurality of modulation symbols.

18. The first wireless device of claim 1, wherein the processing system is further configured to cause the first wireless device to:
parse the plurality of information bits between a plurality of shapers, wherein each shaper of the plurality of shapers is associated with a different modulation order, and wherein, to apply the constellation shaping to the plurality of information bits, the processing system is further configured to cause the first wireless device to:
apply, via each shaper of the plurality of shapers, the constellation shaping to a respective set of information bits from the plurality of information bits to generate a respective stream of shaped information bits; and
interleave the respective streams of information bits to generate a plurality of interleaved, shaped information bits, wherein the plurality of shaped information bits being encoded comprises the plurality of interleaved, shaped information bits being encoded.

19. The first wireless device of claim 18, wherein a respective ratio of bits incrementally fed to each shaper of the plurality of shapers relative to a total quantity of bits fed to the plurality of shapers is fixed.

20. The first wireless device of claim 18, wherein a respective first quantity of information bits incrementally fed to each shaper of the plurality of shapers varies per shaper, and wherein a second quantity of bits output by each shaper is the same.

21. A method for wireless communications at a first wireless device, comprising:
receiving a plurality of information bits for transmission;
applying constellation shaping to the plurality of information bits to generate a plurality of shaped information bits;
encoding the plurality of shaped information bits to generate a stream of parity bits based at least in part on an encoding rate and a modulation order associated with generation of a plurality of modulation symbols, wherein a stream of systematic bits corresponds to the plurality of shaped information bits; and
transmitting the plurality of modulation symbols based at least in part on the stream of parity bits and the stream of systematic bits, wherein a first modulation symbol of the plurality of modulation symbols comprises a first component and a second component, wherein a sign of each component is based at least in part on a respective group of parity bits from the stream of parity bits, wherein an amplitude of each component is based at least in part on a respective group of systematic bits from the stream of systematic bits, and wherein the plurality of modulation symbols are based at least in part on a modulation and coding scheme (MCS), and wherein all systematic bits of the stream of systematic bits and all parity bits of the stream of parity bits are used to generate the plurality of modulation symbols based at least in part on a relationship between the encoding rate and the modulation order.

22. The method of claim 21, wherein the encoding rate is based at least in part on an encoding composition, and wherein the encoding composition is based at least in part on a first quantity of parity bits from the stream of parity bits per codeword generated based at least in part on the encoding and based at least in part on a second quantity of systematic bits from the stream of systematic bits per codeword generated based at least in part on the encoding.

23. The method of claim 22, further comprising:
communicating a control message indicating the modulation order, the encoding composition, or both, wherein the plurality of modulation symbols is based at least in part on the modulation order, the encoding composition, or both.

24. The method of claim 22, wherein the modulation order, the encoding composition, or both, are pre-configured at the first wireless device, and wherein the modulation order, the encoding composition, or both, are based at least in part on the modulation and coding scheme.

25. The method of claim 22, wherein the stream of parity bits comprises a plurality of parity bit segments, and wherein the stream of systematic bits comprises a plurality of systematic bit segments, and wherein each codeword comprises a parity bit segment of the plurality of parity bit segments and a systematic bit segment of the plurality of systematic bit segments, the method further comprising:
adjusting the first quantity of parity bits in each codeword and the second quantity of systematic bits in each codeword based at least in part on adjusting the encoding composition, wherein a ratio between the adjusted first quantity of parity bits and the adjusted second quantity of systematic bits matches a ratio between a third quantity of bits used to generate the sign of each component and a fourth quantity of bits used to generate the amplitude of each component.

26. The method of claim 21, wherein a first sign of the first component is based at least in part on a first group of parity bits of the stream of parity bits, wherein a first amplitude of the first component is based at least in part on a first group of systematic bits of the stream of systematic bits, wherein a second sign of the second component is based at least in part on a second group of parity bits of the stream of parity bit, and wherein a second amplitude of the second component is based at least in part on a second group of systematic bits of the stream of systematic bits.

27. The method of claim 21, wherein a first sign of the first component is based at least in part on a first group of parity bits of the stream of parity bits, wherein a first amplitude of the first component is based at least in part on a first group of systematic bits of the stream of systematic bits and a third group of parity bits from the stream of parity bits, wherein a second sign of the second component is based at least in part on a second group of parity bits of the stream of parity bit, and wherein a second amplitude of the second component is based at least in part on a second group of systematic bits of the stream of systematic bits and a fourth group of parity bits from the stream of parity bits.

28. The method of claim 21, further comprising:
generating a second modulation symbol of the plurality of modulation symbols that comprises a third component and a fourth component, wherein a sign of each component in the second modulation symbol is based at least in part on a respective second group of parity bits from the stream of parity bits, and wherein an amplitude of each component in the second modulation symbol is based at least in part on a respective second group of systematic bits from the stream of systematic bits.

29. A first wireless device for wireless communications, comprising:
means for receiving a plurality of information bits for transmission;
means for applying constellation shaping to the plurality of information bits to generate a plurality of shaped information bits;
means for encoding the plurality of shaped information bits to generate a stream of parity bits based at least in part on an encoding rate and a modulation order associated with generation of a plurality of modulation symbols, wherein a stream of systematic bits corresponds to the plurality of shaped information bits; and
means for transmitting the plurality of modulation symbols based at least in part on the stream of parity bits and the stream of systematic bits, wherein a first modulation symbol of the plurality of modulation symbols comprises a first component and a second component, wherein a sign of each component is based at least in part on a respective group of parity bits from the stream of parity bits, wherein an amplitude of each component is based at least in part on a respective group of systematic bits from the stream of systematic bits, and wherein the plurality of modulation symbols are based at least in part on a modulation and coding scheme (MCS), and wherein all systematic bits of the stream of systematic bits and all parity bits of the stream of parity bits are used to generate the plurality of modulation symbols based at least in part on a relationship between the encoding rate and the modulation order.

30. A non-transitory computer-readable medium storing code for wireless communications, the code comprising instructions executable by one or more processors to:
receive a plurality of information bits for transmission;
apply constellation shaping to the plurality of information bits to generate a plurality of shaped information bits;
encode the plurality of shaped information bits to generate a stream of parity bits based at least in part on an encoding rate and a modulation order associated with generation of a plurality of modulation symbols, wherein a stream of systematic bits corresponds to the plurality of shaped information bits; and
transmit a plurality of modulation symbols based at least in part on the stream of parity bits and the stream of systematic bits, wherein a first modulation symbol of the plurality of modulation symbols comprises a first component and a second component, wherein a sign of each component is based at least in part on a respective group of parity bits from the stream of parity bits, wherein an amplitude of each component is based at least in part on a respective group of systematic bits from the stream of systematic bits, and wherein the plurality of modulation symbols are based at least in part on a modulation and coding scheme (MCS), and wherein all systematic bits of the stream of systematic bits and all parity bits of the stream of parity bits are used to generate the plurality of modulation symbols based at least in part on a relationship between the encoding rate and the modulation order.
